(19) United States
(12) Patent Application Publication
(10) Pub. No.: US 2006/0084260 A1
(43) Pub. Date: Apr. 20, 2006

(54) Copper processing using an ozone-solvent solution

(76) Inventors: David G. Boyers, Los Altos, CA (US); Serdar Aksu, Fair Oaks, CA (US)

Correspondence Address: Joseph H. Smith, P.O. Box 32057, San Jose, CA, 95152, US

(21) Appl. No.: 11/221,250

(22) Filed: Sep. 7, 2005

Related U.S. Application Data
(60) Provisional application No. 60/607,865, filed on Sep. 7, 2004.
(60) Provisional application No. 60/609,200, filed on Sep. 9, 2004.
(60) Provisional application No. 60/612,737, filed on Sep. 24, 2004.
(60) Provisional application No. 60/638,689, filed on Dec. 23, 2004.
(60) Provisional application No. 60/709,209, filed on Aug. 18, 2005.

(51) Int. Cl. H01L 21/4763

(52) U.S. Cl. 438/618

(57) ABSTRACT

The present invention relates to a method and apparatus for treating materials such as copper or copper based metal alloys, used in fabricating semiconductor devices with an ozone solvent solution and avoiding damage to metals by corrosion. The invention is also applicable to treating of materials such as copper and copper based alloys for the purpose of forming a protective layer on the exposed metal surface for protection of those copper surfaces from damage or corrosion caused by subsequent exposure to other liquid, gas, or plasma environments. This can be achieved by properly selecting the composition of the ozone solvent solution and controlling the pH and ORP of the ozone-solvent solution while avoiding the use of certain chemical constituents in the ozone solvent solution.

### 1 CROSS-REFERENCE TO RELATED APPLICATIONS

This patent application claims priority from the following U.S. provisional patent applications:
1) U.S. Provisional Patent Application (60/607,865) filed Sep. 7, 2004, “Method and Apparatus for Treating a Substrate with an Ozone-Solvent Solution—Copper Processing I”, Inventor: D. G. Boyers
2) U.S. Provisional Patent Application (60/609,200) filed Sep. 9, 2004, “Method and Apparatus for Treating a Substrate with an Ozone-Solvent Solution—Copper Processing II”; Inventor: D. G. Boyers
3) U.S. Provisional Patent Application (60/612,737) filed Sep. 24, 2004, “Method and Apparatus for Treating a Substrate with an Ozone-Solvent Solution—Copper Processing III”; Inventor: D. G. Boyers
4) U.S. Provisional Patent Application (60/638,689) filed Dec. 23, 2004, “Method and Apparatus for Treating a Substrate with an Ozone-Solvent Solution—Copper Processing IV”; Inventors: D. G. Boyers and Serdar Aksu,
5) U.S. Provisional Patent Application (60/709,209) filed Aug. 18, 2005, “Method and Apparatus for Treating a Substrate with an Ozone Solvent Solution-Copper Processing V”, Inventor: D. G. Boyers.

Also, the following are hereby incorporated by reference:
6) U.S. application Ser. No. 09/693,012 “A Method and Apparatus for Treating a Substrate with an Ozone-Solvent Solution”, Inventors: D. G. Boyers and J. T. Cremer, Jr.;
7) U.S. application Ser. No. 10/126,073 “Method and Apparatus for Treating a Substrate with an Ozone-Solvent Solution II”, Inventor: D. G. Boyers;
8) U.S. application Ser. No. 10/133,275 “Method and Apparatus for Heating a Gas-Solvent Solution”, Inventor: D. G. Boyers;
9) U.S. application Ser. No. 10/425,692 “Method and Apparatus for Treating a Substrate with an Ozone-Solvent Solution III”, Inventor: D. G. Boyers; and
10) U.S. application Ser. No. 10/886,475 “Method and Apparatus for Treating a Substrate with an Ozone-Solvent Solution IV”, Inventor: D. G. Boyers.

### 1.1 BACKGROUND OF THE INVENTION

1.2 Technical Field

This invention relates to methods, apparatus, and treatment compositions for treating a material with an ozone solvent solution. More particularly, the present invention relates to the corrosion-free treatment of a copper containing materials such as encountered in the fabrication of integrated circuits and other electronic devices and electronic circuits for a number of purposes including, but not limited to cleaning, removing light organic films or contaminants, from those materials, removing heavy organic films such as layers of photo-resist (resist stripping), modifying the wetting characteristics of materials, forming a protective passivation layer on a material, and growing an oxide on a material. The treatment can be for one or more purposes including cleaning, material removal, formation of protective film or protective layer or protective barrier layer on metals such as copper and aluminum, oxidation of a material for the formation of an oxide layer or oxide film on a material such a silicon, removal of an organic material such as photoresist for applications such as FEOL resist rework, FEOL post etch strip, FEOL post implant strip, BEOL resist rework, and BEOL post etch strip, post CMP clean. The treatment can be used for removal of thin layers of organic contamination to promote film adhesion in pre-deposition cleaning applications or post CMP cleaning applications.

1.3 Description of Related Art

1.3.1 Related Ozone Based Processes for Electronic Device Manufacturing:

Nelson et. al. of FSI international disclose a method of treating a substrate with an ozone solvent solution for the purpose of removing photoresist and other organic material from a substrate (Nelson, et. al U.S. Pat. No. 5,971,272) (Carter, et. al U.S. Pat. No. 6,080,531), (Nelson, et. al U.S. Pat. No. 6,406,551B1) None of these patents disclose a method forming an ozone solvent solution for corrosion free treatment of copper. In fact, the principal constituent (NH3 OR NH4+) of their preferred chemistry is one that is damaging to copper because of the formation of soluble ammonia-copper complexes. Small et. al (US2002/0111026 A1) use ammonium salts such as ammonium carbonate mixed with ozone water solutions for use in copper removal in chemical mechanical polishing of semiconductor wafers containing copper and other metals. Semitool Corporation is a manufacturer of an ozone based process and apparatus that is sold under the tradename Hydrozone™ that is marketed for photoresist removal from substrates for semiconductor manufacturing applications. They have a number of patents filed on their process including (Bergman WO 10/071777A1). These patents do not disclose a method of forming an ozone solvent solution for corrosion free treatment of copper. Semitool's web site specifically states that their ozone-water process is not suitable for use with copper. None of these references address the challenge of making an ozone-water based treatment solution capable of forming a protective passivation layer on treated copper surfaces for corrosion free treatment of electronic devices.

1.3.2 Corrosion Control with Benztriazol and Other Organic Corrosion Inhibitors:

The most commonly used method for copper corrosion control in electronic device manufacturing applications is to use an organic corrosion inhibitor such as Benzotriazol (BTA). However, BTA is not ozone compatible and has not been useful for preventing copper corrosion in ozone-water based treatment processes in electronic device manufacturing.

1.3.3 Copper Corrosion Control with Phosphates:

The use of phosphates for corrosion control is known in the art. However, to our knowledge no one has demonstrated a composition for corrosion free treatment of substrates for electronic device manufacturing applications using ozone-water based chemistries formulated for high photoresist removal rates and low copper corrosion rates.

### 2 OBJECTS OF THE INVENTION

2.1 Primary Objects of the Invention
provide minimal copper corrosion—stable adherent protective passivating film formation on copper and no copper corrosion (copper etch rate <10 A°/min)
provide for a protective layer on a copper surface for protection of that copper surface from damage or corrosion caused by exposure to other liquid, gas, or plasma environments
provide high photoresist removal rates, high organic residue removal rates, high material oxidation rates, high material treatment rates, or high material cleaning rates (DUV resist etch rates of the order of 5,000 A°/min)
provide buffering chemistry for pH control
use low cost chemicals
use environmentally benign chemicals
use dilute chemistry
use chemicals already available in semiconductor fabrication facility

2.2 Additional Objects of the Invention—Platform Independent

### Exemplary Implementations of Ozone-Based Processes in Which

ozone is first dissolved in water and then the ozone-water solution is applied to a substrate
the ozone-water solution is heated prior to being applied to a substrate
the ozone-water solution is heated while being applied to a substrate
ozone gas is introduced directly into the process chamber and water and other chemicals such a hydroxyl radical scavengers are applied to a substrate
ozone gas is introduced near a substrate surface and other chemicals are applied to the substrate
ozone gas is introduced directly into the process chamber and water and other chemicals such a hydroxyl radical scavengers are applied to a substrate in vapor form (e.g. humidified ozone gas processes)

### Typical Implementations Include

single wafer or batch (wet bench) immersion processes
single-wafer or batch spin processing
applicable to single-pass-chemistry or circulating chemistry process module designs

2.3 Technical Background

2.3.1 Hydroxyl Radical Scavengers to Stabilize Dissolved Ozone Concentration

Hydroxyl radical scavengers such as carbonates, phosphates and acetates are useful for stabilizing dissolved ozone concentrations in solution for both homogeneous reactions and heterogeneous reactions. However, the ammonia salts such as ammonium carbonate, ammonium bicarbonate, ammonium phosphate, and ammonium acetate used in current processes and current wafer processing treatment solutions are not suitable for use in copper processing. These ammonia salts decrease or eliminate the stability of passivating films that might form on the copper surface and render copper available to corrosive attack. Moreover, use of ammonia salts could decrease the stability of dissolved ozone in aqueous solutions. Ozone is known to react with ammonia and ammonium ions generated by the dissolution of ammonia salts in aqueous solutions, and this reaction could promote ozone decomposition.

2.4 Ozone Generation:

Ozone generators of the type used for forming very high concentration ozone gas typically use a feed gas comprising oxygen mixed with nitrogen. First generation ozone generators such as the MKS Astex AX 8100 or MKS Astex AX8200 require 0.2 to 0.5 percent nitrogen by volume. Second generation ozone generators typically require 50 ppm or more Nitrogen by volume. A generator operating with a mixture containing oxygen mixed with nitrogen form both NO2 gas and ozone gas. The NO2 gas has a very high solubility in water. The NO2 gas dissolved in water forms nitric acid. Nitric acid attacks copper. One of the several elements of the preparing a treatment solution, which will form of a thin stable protective passivating film on treated copper, is to exclude nitric acid from the ozone-water solution. An alternative gas mixture meeting this requirement is oxygen mixed with CO2 gas. First generation ozone generators such as the Astex AX8100 and Astex AX8200 have excellent performance when operated on a mixture of oxygen+10% CO2 by volume. Second generation ozone generators can reportedly operate with satisfactory performance on a mixture of oxygen plus 500 ppm to 20,000 ppm (2%) of CO2 by volume.

### 3 BRIEF SUMMARY OF THE INVENTION

In accordance with preferred embodiments of the invention, an improved method of manufacturing an interconnect or circuit on a substrate is provided. The method is useful for treating substrates comprised at least in part of copper, a copper-containing material, or a copper-containing alloy. The method involves treating a substrate with an ozone-solvent-based surface treatment composition to form an inorganic passivating layer on exposed copper or copper-containing alloy surfaces.

In one embodiment the method of manufacture may firther include the step of forming an ozone-solvent based treatment composition. In one embodiment the step of forming the ozone-based treatment composition may further include the step of forming the ozone-solvent-based treatment composition at a relatively low first temperature where the solubility of ozone gas in the solvent is relatively high.

In another embodiment the method of manufacture may further include reacting the ozone-solvent-based treatment composition with surface of the substrate at a temperature higher than the temperature at which the ozone-solvent-based solution was initially formed.

In another embodiment the method of manufacture may further include the step of heating the ozone-based treatment composition prior to the step of applying the ozone-based treatment composition to the substrate.

In another embodiment the ozone-solvent based solution is heated prior to being applied to the wafer or substrate. In another embodiment the ozone-solvent based solution is heated while being applied to the wafer or substrate.

Also described is an ozone-based treatment composition for use in the method of manufacture that includes ozone gas dissolved in a solvent, at least one acid, and with a sufficient amount of a base or salt not containing any species such as NH3 or NH4+ that form soluble complexes with copper, which are added to adjust the pH and corresponding Eh (the oxidation-reduction potential) to a predetermined value.

The method may further include the step of removing the passivating layer wherein immediately before a subsequent process step the passivation layer is removed from the exposed copper or copper-containing alloy surfaces with a passivation layer removal chemistry.

Also described are methods of forming the treatment composition. Also described are methods and compositions for removal of the passivating layer.

Various embodiments are also described that relate to the method of application of the treatment composition. In one embodiment the treatment composition may be applied by spin processing. In another embodiment the treatment composition may be applied by spraying. In still another embodiment the treatment composition may be applied by immersion or partial immersion of the wafer or substrate in the treatment composition.

In one embodiment the treatment composition may be used in a single pass configuration in which the treatment solution is discarded after contacting the wafer or substrate once. In another embodiment the treatment composition may be used in a circulating configuration in which the treatment solution is reused for treating the same substrate or wafer for an extended duration before being discarded or recycled. In another embodiment the treatment composition may be used in a circulating configuration in which the treatment solution reused for treating more than one substrate or wafer before being discarded or recycled.

In one embodiment the method of manufacture may be used for forming a passivating layer on exposed copper or copper-containing alloy surfaces. Applications include any point in the manufacturing process in which it is useful to protect exposed copper surfaces from corrosion such as that which may arise during the queuing time in which a wafer awaits the next process step. In another embodiment, the method of manufacture may also be used for removing photoresist or other organic materials while forming a passivating layer on exposed copper or copper-containing alloy surfaces. In another embodiment the method of manufacture may also be used for precisely removing a thin layer (less than 10 nm thick) of copper from an exposed copper or copper-containing alloy surface

In one preferred embodiment the ozone gas may be dissolved in a suitable-solvent such as water, with one or more additional acids and bases or salts included to form the treatment composition, provide a pH buffer and provide an hydroxyl radical scavenger, all mixed to form one solution prior to the application of the treatment solution to the substrate or wafer. In another embodiment, the ozone gas may be introduced directly into the process chamber and water and other chemicals such as hydroxyl radical scavengers are applied to a substrate. In another embodiment, ozone gas is introduced near a substrate surface and other chemicals are applied to the substrate. In another embodiment ozone gas is introduced directly into the process chamber and the solvent (water is one preferred solvent) and other chemicals such a hydroxyl radical scavengers are applied to a substrate in vapor form.

Also described are methods of integration of the process into the manufacturing sequence for forming a copper interconnect on a wafer or substrate. Also described are methods of integration of the process into the existing tools used in the manufacture of an interconnect such as wet cleaning tools, polymer cleaning tools, copper plating tools, CMP tools, post CMP cleaning tools. Also described are exemplary apparatus and systems for use in manufacturing a circuit or interconnect on a substrate. The invention also includes interconnects and circuits made by the inventive processes.

### 4 BRIEF DESCRIPTION OF THE DRAWINGS

4.1 E-pH Diagram Drawings

The inventors' measured data is plotted on the diagrams shown in shown (FIGS. 1a, 1b, 1c, 2a, 2b, 3a, 3b, 4a, 4b, 5a, 5b, 6a, and 6b to show the range of pH values for which Cu2O3 and other solid phases may form. The measured data shows the oxidation reduction potential (ORP) with respect to standard hydrogen electrode (SHE) as a function of pH for ozone-gas dissolved in water. The data is for treatment compositions with a carbonate and/or phosphate based additive chemistry titrated to the specified pH with TMAH, and with dissolved ozone concentration ranging from 68 to 88 mg/L.

FIG. 1a: The E-pH diagram calculated by the inventors showing the predominant phases for the Cu—H2O-10 mM CO2 system with total dissolved copper concentration (CuT) of 10−2 mM at T=25 C; the E-pH diagram previously published by Pourbaix is shown in dotted line for comparison. We can see that the region for stable Cu2O3 formation is larger than previously predicted by Pourbaix.

FIGS. 1b and 1c: The E-pH diagrams calculated by the inventors showing the predominant phases for the Cu—H2O-5 mM CO2 system with total dissolved copper concentration (CuT) of 10−2 mM; FIG. 1b is calculated at T=43 C; FIG. 1c is calculated at 53 C. (The inventors have shown that the Cu—H2O-5 mM CH3COOH-5 mM CO2 system has virtually the same E-pH diagrams).

FIGS. 2a and 2b: The E-pH diagrams calculated by the inventors showing the predominant phases for the Cu—H2O-16 mM CO2 system with total dissolved copper concentration (CuT) of 10−2 mM; FIG. 2a is calculated at T=43 C; FIG. 2b is calculated at 53 C.

FIGS. 3a and 3b: The E-pH diagrams calculated by the inventors showing the predominant phases for the Cu—H2O-10 mM H3PO4 system with total dissolved copper concentration (CuT) of 10−2 mM; FIG. 3a is calculated at T=43 C; FIG. 3b is calculated at 53 C. (The inventors have shown that the Cu—H2O-10 mM-H3PO4-5 mM CO2 system has virtually the same E-pH diagrams)

FIGS. 4a and 4b: The E-pH diagrams calculated by the inventors showing the predominant phases for the Cu—H2O-5 mM CH3COOH system with total dissolved copper concentration (CuT) of 10−2 mM; FIG. 4a is calculated at T=43 C; FIG. 4b is calculated at 53 C. (The inventors have shown that the Cu—H2O system has virtually the same E-pH diagrams)

FIGS. 5a and 5b: The E-pH diagrams calculated by the inventors showing the predominant phases for the Cu—H2O-10 mM CH3COOH system with total dissolved copper concentration (CuT) of 10−2 mM; FIG. 5a is calculated at T=43 C; FIG. 5b is calculated at 53 C.

FIGS. 6a and 6b: The E-pH diagram calculated by the inventors showing the predominant phases for the Cu—H2O-5 mM H3PO4 system with total dissolved copper concentration (CuT) of 10−2 mM; FIG. 6a is calculated at T=43 C; FIG. 6b is calculated at 53 C.. (The inventors have shown that Cu—H2O-5 mM-CH3COOH-5 mM H3PO4 system has virtually the same E-pH diagram)

4.2 Apparatus Drawings

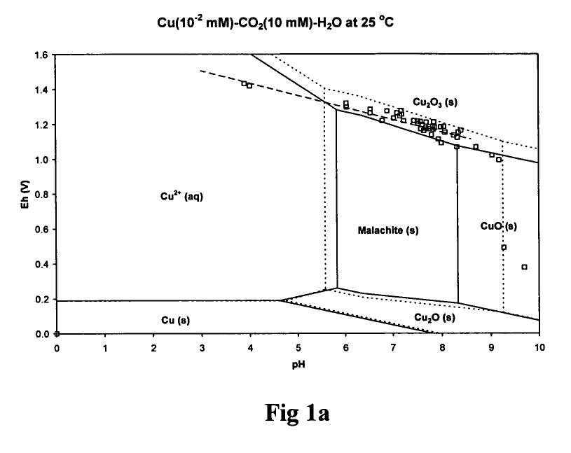

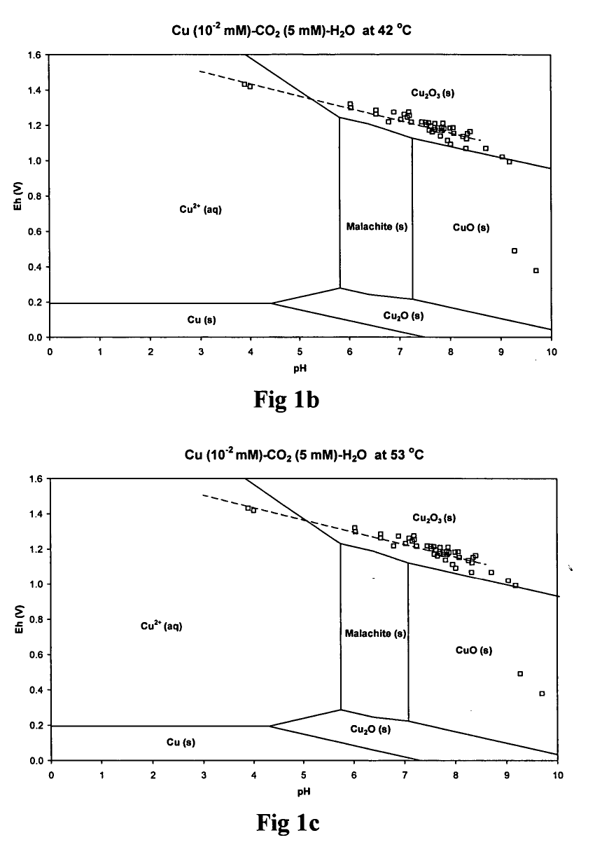

The various features of the present invention and some example preferred embodiments for methods and apparatus may be better understood by referring to the following discussion and the accompanying drawings shown in FIG. 7a, 7b, 8a, and 8b shown in this application in which like reference numerals refer to like elements in the several figures. This invention including, but not limited to, the treatment compositions and methods for the formation of the treatment compositions, and methods of use of the treatment compositions, can also be practiced using any of the configurations shown in FIGS. 1-19 of prior application Ser. No. 09/693,012, “A Method and Apparatus for Treating a Substrate with an Ozone-Solvent Solution”, inventors Boyers and Cremer, incorporated herein by reference. This invention including, but not limited to, the treatment compositions and methods for the formation of the treatment compositions, and methods of use of the treatment compositions can also be practiced using any of the configurations shown in any of the above listed patent applications previously filed by the applicant and incorporated herein by reference. Any of the treatment compositions of this invention may be used with any of the methods and apparatus of this invention.

FIGS. 7a, 7b, 8a and 8b illustrate functional block diagrams of a method of processing materials in which additional gaseous chemicals such as CO2 gas and additional liquid chemicals such as TMAH and H3PO4 and CH3COOH may be injected into the ozone-water solution upstream of the point-of-use.

### DETAILED DESCRIPTION OF THE INVENTION

### 5 Ozone-Solvent-Based Treatment Compositions

5.1 Surface Treatment Compositions—Overview

The inventive ozone-water based treatment solution can be used to treat surfaces to form a protective passivation layer on a metal, for photoresist removal, organic residue removal, cleaning, surface treatment while not etching or damaging metal films containing copper, or aluminum. In the preferred mode, this is accomplished by formulating a treatment solution with the following elements:
does contain a hydroxyl radical scavenger for stabilization of the dissolved ozone concentration in solution
does not contain species which react with dissolved ozone at high rates and accelerate ozone decomposition
does not contain species which etch or attack copper or aluminum
does not contain strong complexing agents, which can increase the copper solubility and interfere with formation of passivating copper oxide films
may contain one or more species which can form passivating protective films other than native copper oxides
does not contain species that attack or etch the passivating film
does contain a pH adjustment and buffering chemistry for setting the pH of the treatment solution to a pH value appropriate for the formation of a passivating film, while providing improved pH control, improved process stability, and a wider process window
does not contain metal hydroxide bases for pH adjustments, which are not acceptable in standard silicon based semiconductor processing
   5.1.1 CO2 Based Copper Passivation Chemistry:

The inventors have shown that CO2 gas dissolved in water with a suitable base added for pH control can form the basis for copper passivation chemistry for electronic device manufacturing. CO2 is readily available in the semiconductor fab. An alternative chemistry may employ a carbonate salt as a source of carbonate ions. The passivation chemistry may contain a suitable base such as TMAH for setting the pH to a predetermined value. The chemistry forms a protective layer on exposed copper surfaces. The E-pH diagram for Cu—CO2—H2O system at 25° C. was calculated and published by Pourbaix in 1973. Using the most recent thermodynamic data, the inventors re-calculated E-pH diagrams for Cu—CO2—H2O system at 25° C., and other specified temperatures. According to the E-pH diagrams calculated by inventors (see FIGS. 1a-6b), the stable solid phases that could form on exposed copper surfaces in the pH range of approximately 6 to 8.5 are believed to be tenorite (CuO), malachite CuCO3Cu(OH)2 and copper sesquioxide (Cu2O3) in CO2 based copper passivation chemistries. The E-pH diagrams calculated by the investors indicate that copper sesquioxide formation should indeed be expected at lower potentials than those calculated by Pourbaix. The formation of passivating film with Cu2O3 was, therefore, not obvious in view of the prior published work. While formation of tenorite and malachite layers can protect copper from corrosive attack, a passivating layer formed with copper sesquioxide is believed to be more protective. Triplex passivating layers such as Cu2O/CuO/Cu2O3 or Cu2O/Malachite/Cu2O3 are believed to be more protective than duplex passivating layers such as Cu2O/CuO or Cu2O/Malachite.

When CO2 gas is dissolved in water the dissolved CO2 concentration in mg/liter or millimoles per liter is a function of the partial pressure of the CO2 gas and the temperature of the water. Data on the solubility of CO2 in water as a function of CO2 partial pressure in bar and water temperature in degree C. for a range of values is presented in the Table 1 below. We can see that increasing the partial pressure increases the dissolved concentration and that decreasing the water temperature increases the dissolved concentration.

TABLE 1
Solubility of carbon dioxide (CO2) gas in water as a function of
CO2 partial pressure in bar and water temperature in degree C.: The
dissolved CO2 concentration is given in both mg/liter
and millimoles/liter. CO2 MW = 44 grams/mole

| | CO2 partial | | CO2 partial | | CO2 partial | |
|---|---|---|---|---|---|---|
| | pressure p = 0.1 bar | | pressure p = 0.2 bar | | pressure p = 0.3 bar | |
| | (1.45 (psia) | | (2.9 psia) | | (4.35 psia) | |
| | Conc. | Conc. | Conc. | Conc. | Conc. | Conc. |
| | mg/L | millimoles/L | mg/L | millimoles/L | mg/L | millimoles/L |
| 5° C. | 275.8 | 6.27 | 552.2 | 12.55 | 829.2 | 18.85 |
| 8° C. | 248.0 | 5.64 | 496.5 | 11.28 | 745.4 | 16.93 |
| 42° C. | 98.9 | 2.25 | 198.0 | 4.50 | 297.1 | 6.75 |
| 53° C. | 76.6 | 1.74 | 153.2 | 3.48 | 230.1 | 5.23 |

5.1.2 H3PO4 Based Copper Passivation Chemistry:

The inventors have shown that phosphoric acid (H3PO4), with a pKa of 7.2 for the dissociation of H2PO4-1 to HPO4-2, can form the basis for a copper passivation chemistry for electronic device manufacturing. An alternative chemistry may employ a salt of phosphoric acid as source of phosphate ions. The H3PO4 based approach is a preferred approach since this chemistry is readily available in the semiconductor fab. The passivation chemistry may additionally contain CO2 and a suitable base such as TMAH for setting the pH to a predetermined value. The chemistry forms a protective layer on exposed copper surfaces. In the embodiment which employs both phosphoric acid and CO2, the stable solid phases that could form on exposed copper surfaces are believed to be tenorite, malachite, copper (II) phosphate and copper sesquioxide. In embodiments which employ much more H3PO4 than CO2 (10 mM/L H3PO4 and 0.5 mM/L CO2, for example), the stable solid phases that could form on exposed copper surfaces are believed to be tenorite, copper (II) phosphate and copper sesquioxide. In embodiments which employ much less H3PO4 than CO2 (0.5 mM/L H3PO4 and 5 mM/L CO2, for example), the stable solid phases that could form on exposed copper surfaces are believed to be tenorite, malachite and copper sesquioxide. While formation of tenorite, malachite and copper (II) phosphate layers can protect copper from corrosive attack, a passivating layer formned with copper sesquioxide is believed to be more protective. The inventors constructed the E-pH diagrams for the first time showing the stability regions of different copper species for the H3PO4 based copper passivation chemistries (See the FIG. 1a-6b). H3PO4 based chemistry has at least two advantages over CO2 based chemistry. First, the concentration of H3PO4 in solution is not dependent upon the solubility of a gas in solution as in the case of CO2 and therefore concentration is more readily maintained. Second, H3PO4 has a pKa of a about 7.3 and thereby provides good buffering up to a pH of about pKa+1˜8.3. This passivation chemistry may also be used with aluminum conductors. In embodiments which employ H3PO4, the stable solid phase formed on exposed aluminum surfaces is believed to be Al2O3 or an aluminum phosphate. This chemistry also provides a good source of HO radical scavenger species and enhanced etch rates for organic materials such as photoresist and enhanced treatment rates for other applications.

5.1.3 CH3COOH Based Copper Passivation Chemistry:

The inventors have shown that acetic acid (CH3COOH) with a pKa of 4.75 can the basis for a copper passivation chemistry for electronic device manufacturing. An alternative chemistry may employ a salt of acetic acid as source of acetate ions. The acetic acid based approach is preferred since this chemistry is readily available in the semiconductor fab. The passivation chemistry may additionally contain CO2 and/or H3PO4 and a suitable base such as TMAH for setting the pH to a predetermined value. The chemistry forms a protective layer on exposed copper surfaces. In the embodiment which employs both acetic acid an/or an acetate salt and CO2, the stable solid phases that could form on exposed copper surfaces are believed to be tenorite and copper sesquioxide. In embodiments which employ much more acetate than CO2 (10 mM/L CH3COOH and 0.5 mM/L CO2 for example), the stable solid phase formed on exposed copper surfaces are believed to be tenorite and copper sesquioxide. In embodiments which employ much less acetate than CO2 (0.5 mM/L CH3COOH and 5 mM/L CO2 for example), the stable solid phase formed on exposed copper surfaces are believed to be tenorite, malachite and Cu2O3. While formation of tenorite and malachite layers can protect copper from corrosive attack, a passivating layer formed with copper sesquioxide (Cu2O3) is believed to be more protective. The inventors constructed the E-pH diagrams for the first time showing the stability regions of different copper species for the CH3COOH based copper passivation chemistries (See the FIG. 1a-6b). This chemistry also provides a good source of HO radical scavenger species and enhanced etch rates for organic materials such as photoresist and enhanced treatment rates for other applications.

5.1.4 Weak Carboxylic Acid Based Copper Passivation Chemistry:

Other weak carboxylic acids such as formic(methanoic) acid, propanoic (propionic) acid, butanoic (butyric) acid, pentanoic(valeric) acid, hexanoic(caproic) acid, heptanoic (enanthic) acid, actanoic(caprylic) acid, nonanoic(pelargonic) acid and decanoic(capric) acid, and salts of these carboxylic acids, could also be used to form the basis for the passivation chemistry outlined here. The passivation chemistry may additionally contain CO2 and/or H3PO4 and a suitable base such as TMAH for setting the pH to a predetermined value. The inventors have shown that these other weak carboxylic acid based compositions have E-pH diagrams very similar to those calculated by the inventors for those chemistries containing the weak carboxylic acid CH3COOH (acetic acid). According to the E-pH diagrams calculated by the inventors (see FIG. 1a-6b), there is no stable solid phase containing only copper and acetate in the case of acetic acid. This is also true in the case of other weak carboxylic acids. The E-pH diagrams calculated here indicate that it is still possible to use weak carboxylic acids to form the basis for the passivation chemistry, as these do not substantially decrease the stability of other copper solid phases such as tenorite, malachite, Cu3(PO4)2 or copper sesquioxide that might be forming on the copper surface. The major selection criteria for the weak carboxylic acids are established as:
not increase the solubility of protective copper solid phases
be a good hydroxyl radical scavenger
   5.1.5 Damage Free Cleaning and Surface Treatment of SiCOH Low k Materials:

The inventors have also demonstrated that the compositions of this invention also provide for low damage processing of leading CVD SiCOH low k materials such as Black Diamon™, Coral™, and Aurora™.

5.2 Surface Treatment Compositions—Comparative Examples

Performance data measured by the inventors is presented in Table 2 below. The goal is to achieve a copper etch rate (copper corrosion rate) of 10 A°/min or less and a DUV photoresist etch rate of 5000 A°/min or more as that demonstrated in example 5 in Table 2 below, example 6 in Table 2 below, and example 7 in Table 2 below.

TABLE 2
Summary of Comparative Examples 1-7:

| PROCESS | | | | | | | |
|---|---|---|---|---|---|---|---|
| PARAMETER | Ex. # 1 | Ex. # 2 | Ex. # 3 | Ex. # 4 | Ex. # 5 | Ex. # 6 | Ex. # 7 |
| CONDITIONS IN | | | | | | | |
| OZONE-WATER | | | | | | | |
| SOLUTION SUPPLY | | | | | | | |
| CONTACTOR | | | | | | | |
| O3—H2O Solution Temp. | 8 | 8 | 8 | 8 | 8 | 8 | 8 |
| (° C.) | | | | | | | |
| Injected O3 Gas | 240 | 240 | 240 | 240 | 240 | 240 | 240 |
| Concentration (g/Nm3) | | | | | | | |
| Solution ORP (note 1) | 1300 | 1300 | 1300 | 1300 | 1300 | 1300 | 1300 |
| (mV) | | | | | | | |
| Solution ORP (SHE) | 1500 | 1500 | 1500 | 1500 | 1500 | 1500 | 1500 |
| (note 2) (mV) | | | | | | | |
| O3 Generator Inlet Gas | O2 + 2% | O2 + 2% | O2 + 2% | O2 + 10% | O2 + 10% | O2 + 10% | O2 + 10% |
| Composition by Vol | N2 | N2 | N2 | CO2 | CO2 | CO2 | CO2 |
| O3 Generator Gas Flow | 0.48 | 0.48 | 0.48 | 0.48 | 0.48 | 0.48 | 0.48 |
| Rate (L/min) | | | | | | | |
| O3 Gas Partial Pressure | 0.78 | >.95 | 0.78 | 0.9 | 0.7 | 0.9 | 0.9 |
| (bar) | | | | | | | |
| CO2 Gas partial pressure | 0.22 | <.05 | 0.22 | 0.1 | 0.3 | 0.1 | 0.1 |
| (bar) | | | | | | | |
| Calc. DissolvedCO2 | 12.4 | NA | 12.4 | 5.64 | 16.9 | 5.64 | 5.64 |
| Conc. at 8° C. (mM/L) | | | | | | | |
| Calc. DissolvedCO2 | 4.95 | <1 | 4.95 | 2.25 | 6.75 | 2.25 | NA |
| Conc. at 42° C. (mM/L) | | | | | | | |
| Calc. DissolvedCO2 | NA | NA | NA | NA | NA | NA | 1.74 |
| Conc. at 53° C. (mM/L) | | | | | | | |
| Solution HNO3 | Not | Not | Not | 0 | 0 | 0 | 0 |
| Concentration (Conc.) | Meas. | Meas. | Meas. | | | | |
| CONDITIONS | | | | | | | |
| DOWNSTREAM OF | | | | | | | |
| HEATER AND | | | | | | | |
| CHEMICAL | | | | | | | |
| INJECTOR(S) | | | | | | | |
| O3—H2O Solution | 42 | 42 | 42 | 42 | 42 | 43 | 53 |
| Temperature (° C.) | | | | | | | |
| O3—H2O Solution Flow | 2 | 2 | 2 | 2 | 2 | 2 | 2 |
| Rate (L/min) | | | | | | | |
| Chemical 1 | NH4HCO3 | NH4HCO3 | TMAH | TMAH | TMAH | TMAH | TMAH |
| Chemical 1 Injection | 0.74 | 0.74 | 2.1 | 0.615 | 2.3 | 0.99 | 0.99 |
| Flow Rate (mL/sec) | | | | | | | |
| mixing ratio: Chem. 1 | 1/45 | 1/45 | 2.1/33.3 | 0.0185 | 0.0153 | 0.0297 | 0.0297 |
| flow/O3—H2O flow | | | | | | | |
| Chemical 1 - Final | 22.2 | 22.2 | 16.4 | 4.8 | 18 | 25 | 24.7 |
| Mixed Conc. (mM/L) | | | | | | | |
| Chemical 2 | NA | NA | NA | NA | NA | H3PO4 | H3PO4 |
| Chemical 2 Injection | NA | NA | NA | NA | NA | 1.1 | 1.1 |
| Flow Rate (mL/sec) | | | | | | | |
| mixing ratio: Chem. 2 | NA | NA | NA | NA | NA | 0.033 | 0.033 |
| flow/O3—H2O flow | | | | | | | |
| Chemical 2 - Final | NA | NA | NA | NA | NA | 11.1 | 11.0 |
| Mixed Conc. (mM/L) | | | | | | | |
| Nominal Dispensed | 66 | 68 | 64 | 85 | 68 | 88 | 85 |
| Dissolved O3 Conc. | | | | | | | |
| (mg/L) | | | | | | | |
| Dispensed Solution pH | 6.7 | 7.5 | 7.8 | 8.32+ | 8.35 | 7.67 | 7.65 |
| Dispensed Solution ORP | Not | Not | Not | 875 | 960 | 999 | 978 |
| (note 1) | Meas. | Meas. | Meas. | | | | |
| Dispensed Solution ORP | ˜1250 | ˜1250 | ˜1150 | 1068 | 1153 | 1192 | 1171 |
| (SHE) (note 2) | | | | | | | |
| Wafer/Substrate RPM | 2000 | 2000 | 2000 | 2000 | 2000 | 2000 | 2000 |
| ON WAFER RESULTS | | | | | | | |
| Maximum Resist Etch | NA | NA | NA | NA | 6848 | 9096 | 12950 |
| Rate (A°/min) | | | | | | | |
| Copper Etch Rate | ˜300 | ˜900 | ˜180 | ˜50 | ˜11 | ˜7 | 8 |
| (A°/min) | | | | | | | |
| Predicted Solid Phase | NA | NA | NA | CuO or | CuO or | Cu2O3 | Cu2O3 |
| Formed on Copper at | | | | Cu2O3 | Cu2O3 | | |
| measured pH and | | | | | | | |
| Measured ORP(SHE) | | | | | | | |

Notes Relating to Examples:
Ex. #1 (Example 1): (O3 + O2 + H2O + CO2 + HNO3 + NH4HCO3, pH: 6.7) - high copper etch rate;
Ex. #2 (Example 2): (O3 + O2 + H2O + CO2 + HNO3 + NH4HCO3, pH: 7.5) - high copper etch rate;
Ex. #3 (Example 3): (O3 + O2 + H2O + CO2 + HNO3 + TMAH, pH: 7.8) - high copper etch rate;
Ex. #4 (Example 4): 0.1 bar CO2 partial pressure + TMAH (A3: O3 + O2 + H2O + CO2 + TMAH, pH 8.32);
Ex. #5 (Example 5): 0.3 bar CO2 partial pressure + TMAH (A4: O3 + O2 + H2O + CO2 + TMAH, pH 8.35);
Ex. #6 (Example 6): 0.1 bar CO2 partial pressure + H3PO4 + TMAH (A5: O3 + O2 + H2O + CO2 + H3PO4 TMAH, pH 7.67);
Ex. #7 (Example 7): 0.1 bar CO2 partial pressure + H3PO4 + TMAH (A5: O3 + O2 + H2O + CO2 + H3PO4 TMAH, pH 7.65)
Other Notes
note 1: oxidation reduction potential with respect to the Ag/AgCl reference electrode
note 2: oxidation reduction potential with respect to the standard hydrogen electrode

5.3 Surface Treatment Compositions—Calculated E-pH Diagrams

The inventors' measured data is plotted on the diagrams shown in FIGS. 1a-6b to show the range of pH values for which Cu2O3 and other solid phases may form. The measured data shows the oxidation reduction potential (ORP) with respect to standard hydrogen electrode (SHE) as a function of pH for ozone-gas dissolved in water. The data is for treatment compositions with a carbonate and/or phosphate based additive chemistry titrated to the specified pH with TMAH, and with dissolved ozone concentration ranging from 68 to 88 mg/L.

Inventors have used the most recent thermodynamical data available in the literature in calculation of the E-pH diagrams presented in FIGS. 1a-6b. The newer thermodynamical data predict copper sesquioxide (Cu2O3) formation at lower potentials than indicated by Pourbaix earlier. (See FIG. 1a) Therefore, the new E-pH diagrams presented here show the possibility of Cu2O3 formation on the copper surface in aqueous passivation chemistries containing dissolved ozone for the first time. Under the conditions where Cu2O3 is stable, copper is expected to form a triplex passivating layer structure: inner copper(I) oxide layer such as Cu2O and middle Cu(II) solid layer, such as tenorite, malachite and Cu3(PO4)2 and outermost Cu2O3 layer. It is believed that this triplex passivating layer structure is highly protective.

Copper sesquioxide is not a very stable solid phase and could be only formed at relatively high positive potentials of the oxygen evolution regime over the water stability region. It can decompose to CuO and O2 according to the following reversible chemical reaction:
Cu2O3→2CuO+0.5 O2.

The oxidation reduction potentials of the treatment solutions developed by the inventors are high enough to form triplex passivating layer structure with Cu2O3 on the copper surface for the specified pH ranges. In addition, the presence of high amounts of dissolved O2 in the treatment solutions is believed to slow down the Cu2O3 decomposition by promoting reverse reaction above.

The ORP-pH regression line displayed on the Eh-pH diagrams was calculated using the experimentally measured ORP data at 42 and 53° C. in the pH range between pH's approximately 4 to 8.5. The equation of this regression line was determined as:
E (in millivolts)=1717−70 pH

The slope of the regression line (−70 mV/pH unit) is very close to the slopes that might be expected in the half-cell electrochemical reactions for O3O2 or O3/H2O couples at temperatures 42 and 53° C. The slopes for the listed couples are −62.5 and −64.7 at 42 and 53° C., respectively. The intercept of the regression line on the potential axis at pH=0 is 1717 mV, which falls in between the standard half-cell potentials for O3/O2 (2076 mV) and O3/H2O (1511 mV).

In reference to FIG. 1a, we present the E-pH diagram calculated by the inventors showing the predominant phases for the Cu—H2O-10 mM CO2 system with total dissolved copper concentration (CuT) of 10−2 mM at T=25 C; the E-pH diagram previously published by Pourbaix is shown in dotted line for comparison. We can see that the region for stable Cu2O3 formation is larger that previously predicted by Pourbaix.

In reference to FIG. 1b and FIG. 1c we present the E-pH diagrams calculated by the inventors showing the predominant phases for the Cu—H2O-5 mM CO2 system with CuT=10−2 mM; FIG. 1b is calculated at T=43 C; FIG. 1c is calculated at T=53 C; the inventors have shown that the Cu—H2O-5 mM CH3COOH-5 mM CO2 system at T=43 C has virtually the same E-pH diagram; these diagrams differ from that calculated by Pourbaix in the published reference.

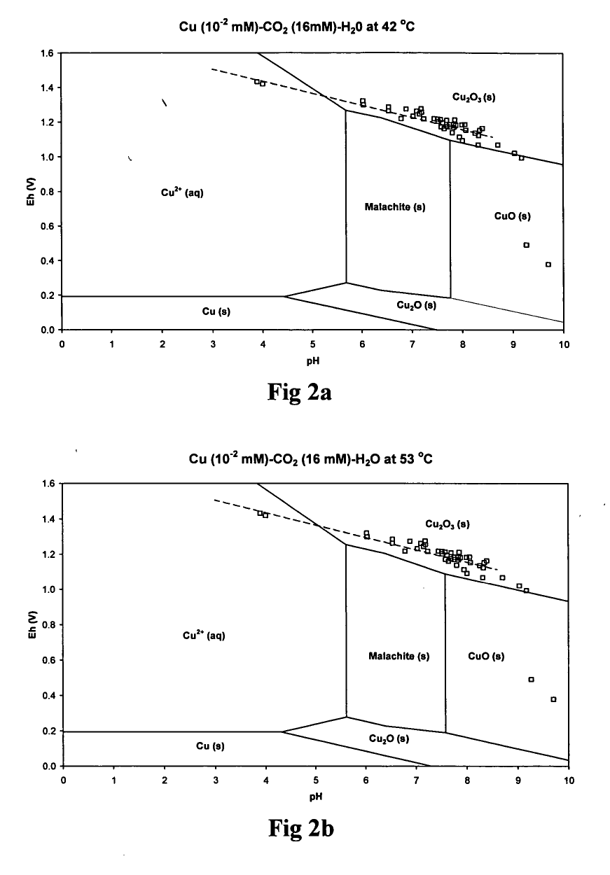

In reference to FIGS. 2a and 2b we present the E-pH diagrams calculated by the inventors showing the predominant phases for the Cu—H2O-16 mM CO2 system with CuT=10−2 mM; FIG. 2a is calculated at T=43 C; FIG. 2b is calculated at T=53 C; these diagrams differs from that calculated by Pourbaix in the published reference.

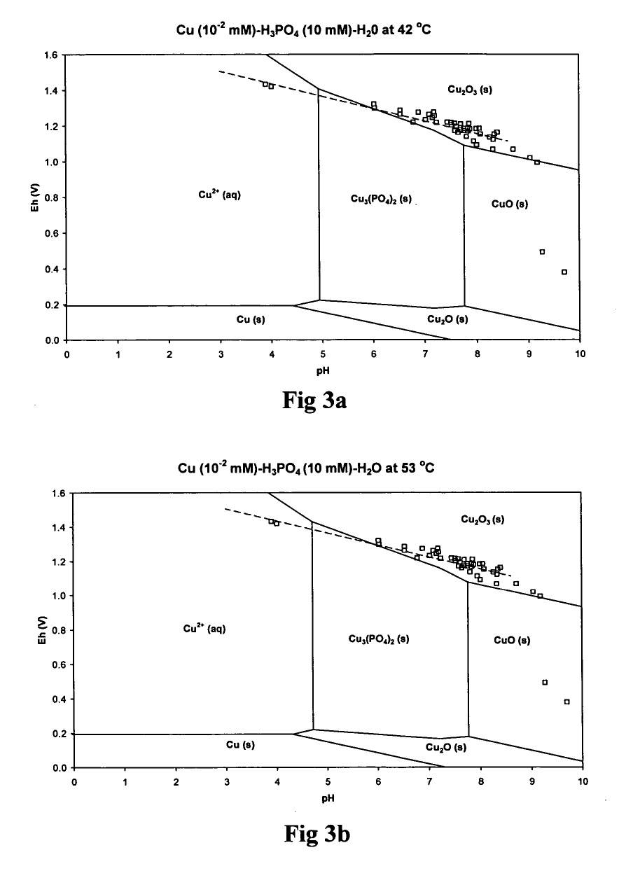

In reference to FIGS. 3a and 3b we present the E-pH diagrams calculated by the inventors showing the predominant phases for the Cu—H2O-10 mM H3PO4-5 mM CO2 system with CuT=10−2 mM; FIG. 3a is calculated at T=43 C; FIG. 3b is calculated at T=53 C; the inventors have shown that the Cu—H2O-10 mM H3PO4 system has virtually the same E-pH diagrams.

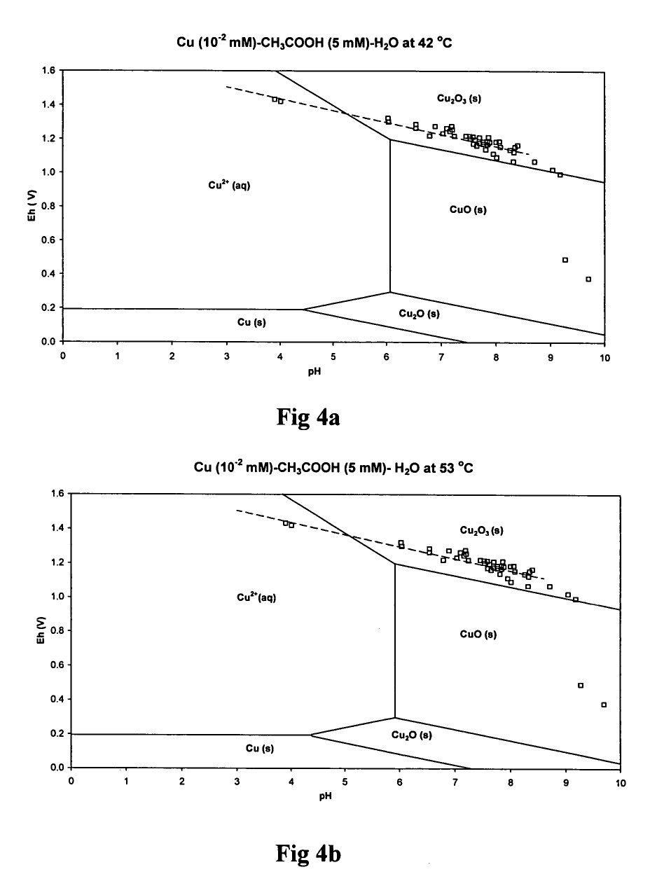

In reference to FIGS. 4a and 4b we present the E-pH diagrams calculated by the inventors showing the predominant phases for the Cu—H2O-5 mM CH3COOH system with CuT=10−2 mM; FIG. 4a is calculated at T=43 C; FIG. 4b is calculated at T=53 C; the inventors have shown that the Cu—H2O system has virtually the same E-pH diagrams.

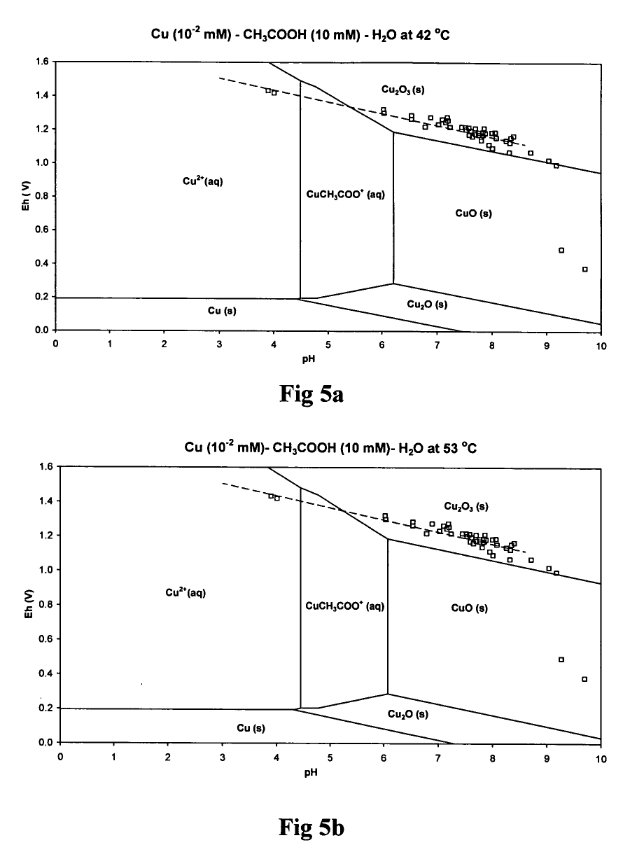

In reference to FIGS. 5a and 5b we present the E-pH diagrams calculated by the inventors showing the predominant phases for the Cu—H2O-10 mM CH3COOH system with CuT=10−2 mM; FIG. 5a is calculated at T=43 C; FIG. 5b is calculated at T=53 C.

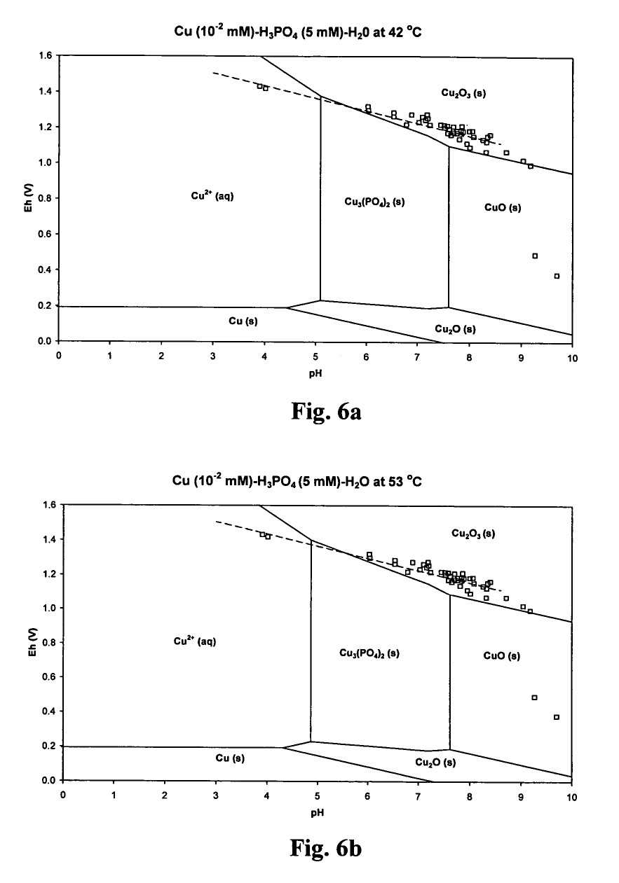

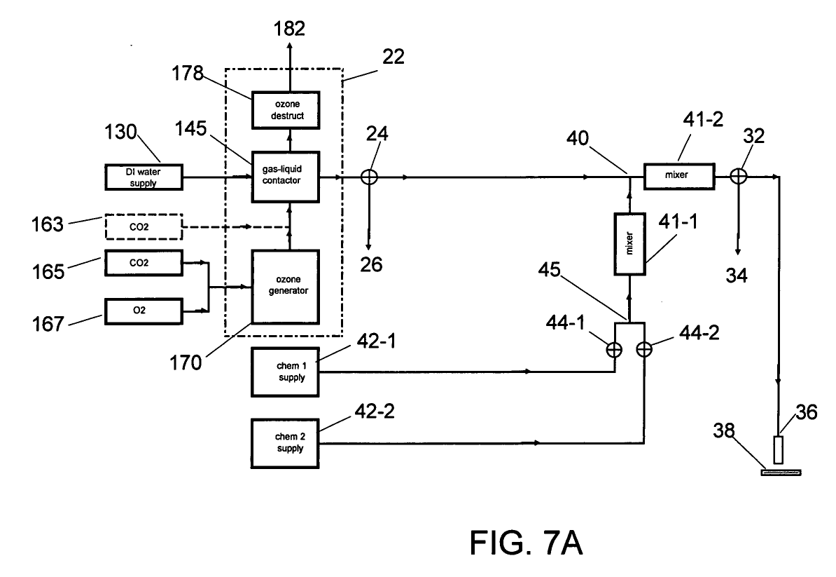

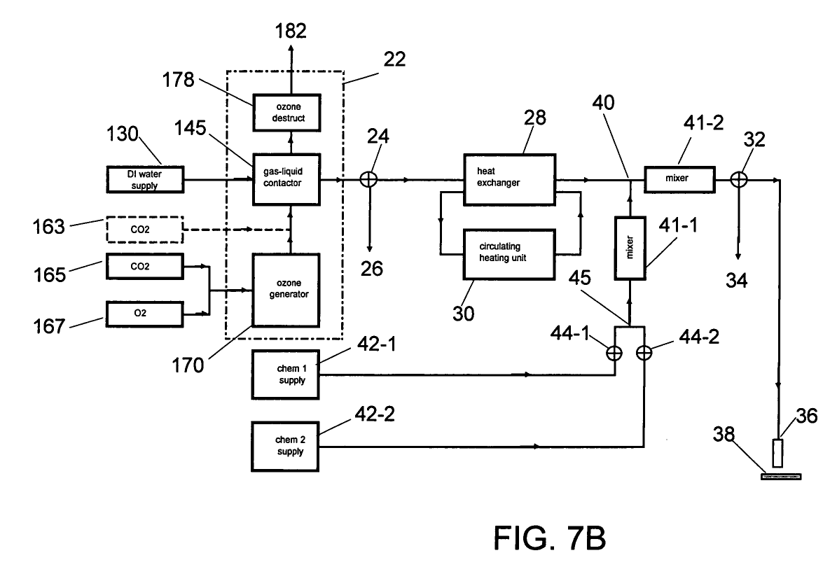

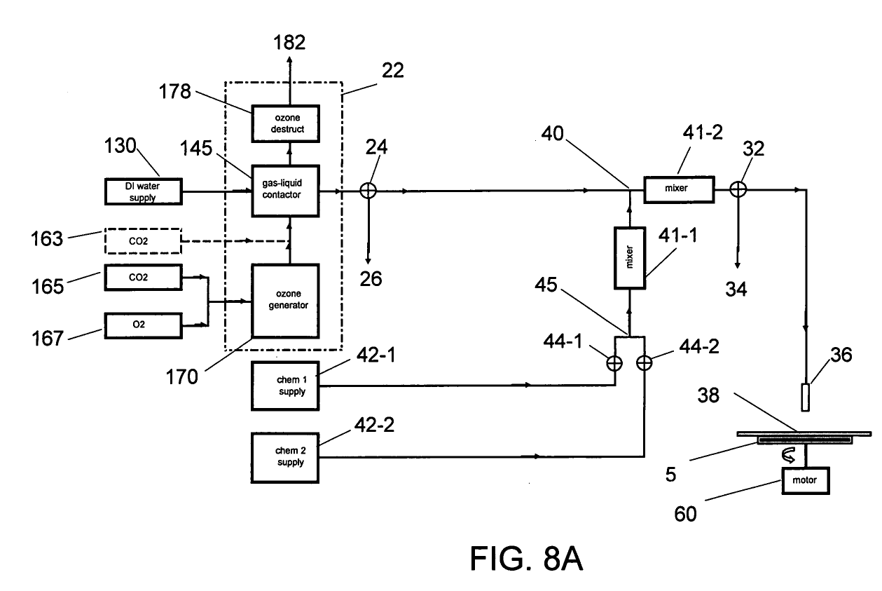

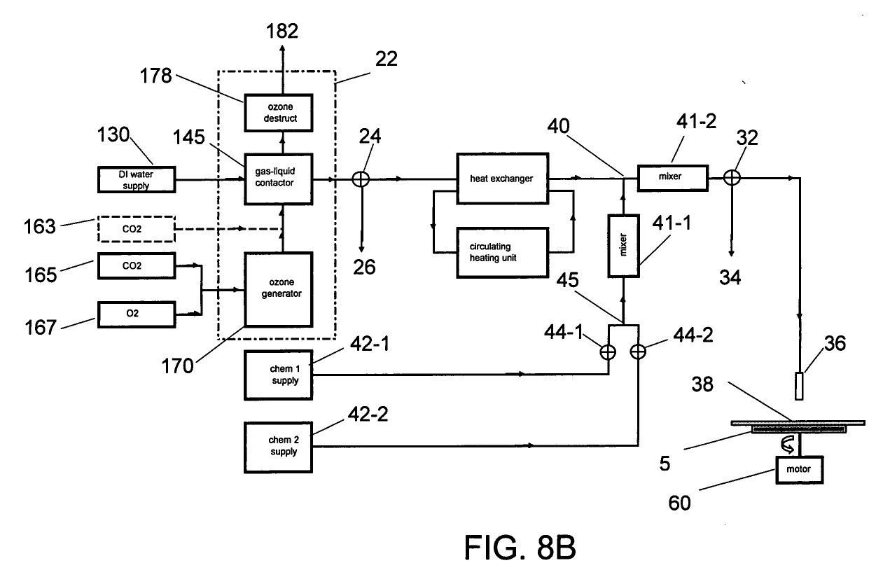

In reference to FIG. 6a and FIG. 6b we present the E-pH diagrams calculated by the inventors showing the predominant phases for the Cu—H2O-5 mM CH3COOH-5 mM H3PO4 system with CuT=10−2 mM; FIG. 6a is calculated at T=43 C; FIG. 6b is calculated at T=53 C; the inventors have shown that Cu—H2O-5 mM H3PO4 system has virtually the same E-pH diagrams.

A summary of some example compositions and the corresponding applicable E-pH diagram is summarized in Table 3.

TABLE 3
Summary of example compositions and applicable E-pH diagram.

| | | E-pH |
|---|---|---|
| | | Diagram |
| System | T | (FIG. |
| (Total Dissolved Cu Concentration = 10 − 2 mM) | (° C.) | Number) |
| Cu—H2O—CO2 (5 mM) | 42 | |
| Cu—H2O—CO2 (5 mM) | 53 | |
| Cu—H2O—CO2 (16 mM) | 42 | |
| Cu—H2O—CO2 (16 mM) | 53 | |
| Cu—H2O—H3PO4 (10 mM) | 42 | |
| Cu—H2O—H3PO4 (10 mM) | 53 | |
| Cu—H2O—CH3COOH (10 mM) | 42 | |
| Cu—H2O—CH3COOH (10 mM) | 53 | |
| Cu—H2O—CH3COOH (5 mM) | 42 | |
| Cu—H2O—CH3COOH (5 mM) | 53 | |
| Cu—H2O | 42 | |
| Cu—H2O | 53 | |
| Cu—H2O—H3PO4 (10 mM)—CO2 (5 mM) | 42 | |
| Cu—H2O—H3PO4 (10 mM)—CO2 (5 mM) | 53 | |
| Cu—H2O—CH3COOH (5 mM)—CO2 (5 mM) | 42 | |
| Cu—H2O—CH3COOH (5 mM)—CO2 (5 mM) | 53 | |
| Cu—H2O—CH3COOH (5 mM)—H3PO4 (5 mM) | 42 | |
| Cu—H2O—CH3COOH (5 mM)—H3PO4 (5 mM) | 53 | |

In Table 4 we have summarized the pH range of stability for solid species such as Malachite, Tenorite (CuO), and Cu3(PO4)2 forming below the stability region of copper sesquioxide (Cu2O3) for different process conditions calculated by the inventors.

TABLE 4
The pH range of stability for solid species forming below the stability region of
copper sesquioxide (Cu2O3) for different process conditions.

| | | T | pH | pH | |
|---|---|---|---|---|---|
| System | Solid Phase | (° C.) | min | max | FIG. |
| Cu (10-2 mM)—CO2 (5 mM)—H2O | Malachite | 25 | 5.9 | 8.0 | NA |
| or | | 42 | 5.8 | 7.3 | |
| Cu (10-2 mM)—CH3COOH | | 53 | 5.7 | 7.1 | |
| (5 mM)—CO2 (5 mM)—H2O | Tenorite | 25 | 8.0 | 13.4 | NA |
| | | 42 | 7.3 | 12.6 | |
| | | 53 | 7.1 | 12.0 | |
| Cu (10-2 mM)—CO2 (16 mM)—H2O | Malachite | 25 | 5.8 | 8.5 | NA |
| | | 42 | 5.7 | 7.8 | |
| | | 53 | 5.6 | 7.6 | |
| | Tenorite | 25 | 8.5 | 13.4 | NA |
| | | 42 | 7.8 | 12.6 | |
| | | 53 | 7.6 | 12.0 | |
| Cu (10-2 mM)—H3PO4 (10 mM)—H2O | Cu3(PO4)2 | 25 | 6.1 | 7.5 | NA |
| or | | 42 | 4.9 | 7.6 | |
| | | 53 | 4.7 | 7.8 | |
| Cu (10-2 mM)—H3PO4 | Tenorite | 25 | 7.5 | 13.4 | NA |
| (10 mM)—CO2 (5 mM)—H2O | | 42 | 7.6 | 12.6 | |
| | | 53 | 7.8 | 12.0 | |
| Cu (10-2 mM)—CH3COOH | Tenorite | 25 | 6.4 | 13.4 | NA |
| (5 mM)—H2O | | 42 | 6.1 | 12.6 | |
| | | 53 | 6.0 | 12.0 | |
| Cu (10-2 mM)—CH3COOH | Tenorite | 25 | 6.8 | 13.4 | NA |
| (10 mM)—H2O | | 42 | 6.2 | 12.6 | |
| | | 53 | 6.1 | 12.0 | |
| Cu (10-2 mM)—CH3COOH | Cu3(PO4)2 | 25 | 5.6 | 7.4 | NA |
| (5 mM)—H3PO4 (5 mM)—H2O | | 42 | 5.0 | 7.6 | |
| | | 53 | 4.9 | 7.6 | |
| | Tenorite | 25 | 7.4 | 13.4 | NA |
| | | 42 | 7.6 | 12.6 | |
| | | 53 | 7.6 | 12.0 | |

CO2 Containing Compositions: In one preferred embodiment the pH is set to approximately one unit above the pKa for H2CO3. This is within a region of good pH buffering and wide process window, within the predicted region for protective film formation, and within the region for high [HCO3-1] concentration for good HO radical scavenging. (note: pKal for H2CO3-6.3 at 20 degree C.)
H3PO4 Containing Compositions: In another preferred embodiment the pH is set to approximately one unit above the pKa for the dissociation of H2PO4-1 to HPO4-2. This is within a region of good pH buffering and wide process window, within the predicted region for protective film formation, and within the region for high [H2PO4-2] concentration for good HO radical scavenging. (note: pKa for the dissociation of H2PO4-1 to HPO4-2 is 7.2 at 20 degrees)
CO2 Containing Compositions: In compositions containing CO2, it is possible to protect copper from active corrosion by forming protective layers tenorite [CuO], malachite [CuCO3Cu(OH)2] and copper sesquioxide [Cu2O3] on the copper surface. While tenorite and malachite can be formed at relatively lower Eh (potential with respect to standard hydrogen electrode) values, formation of copper sesquioxide requires relatively higher Eh values according to the E-pH diagram for the Cu—CO2—H2O system. Protective layers with tenorite and malachite are believed to have a duplex structure; inner copper(I) oxide layer and outer tenorite or malachite layer. At relatively higher Eh values where copper sesquioxide is possible to form, the protective layers are believed to have a triplex structure: inner copper(I) oxide layer and middle tenorite or malachite layer and outermost copper sesquioxide. The triplex layer structure with copper sesquioxide is believed to be more protective than the duplex layer structure with tenorite and malachite. The operation at a pH value of 6.3 to 7.3 can offer good buffering against pH changes since this is no more than 1 pH unit above the pKa of carbonic acid. This can provide better process control and a wider process window. This same operating point of 1 pH unit above the pKa insures that the concentration of the hydroxyl radical scavenger HCO3-1 is IO times the concentration of H2CO3. This insures a higher concentration of hydroxyl radical scavenger for a given CO2 concentration for stabilization of the dissolved ozone concentration and a corresponding higher rate of removal of organic materials such as photoresist. Accordingly, a pH of the order of 7.3, can provide for low copper etch rate (low copper corrosion) and a high photoresist etch rate (high resist strip rate). See Table 5 and the referenced E-pH diagrams.
H3PO4 Containing Compositions: In compositions containing H3PO4 (10 mM/L for example) and a level of dissolved CO2 (<1 mM/L for example), the optimum pH value for formation of a passivating Cu2O3 protective layer on copper and for low copper corrosion, is believed to be in the range 7 to 8.3. This is believed to be in the region of the E-pH diagram for the Cu—H3PO4—H2O system for formation of Cu2O3. The inventors are not aware of published E-pH diagrams for Cu—H3PO4—H2O system or Cu—CO2—H3PO4—H2O system but these E-pH diagrams have been computed by the inventors. In compositions containing H3PO4 (10 mM/L for example) and a low level of CO2 (<1 mM/L for example), operation at a pH of 7.2 to 8.2 can provide for good buffering against pH changes, better process control, and a wider process window. Operation at a pH above the pKa of 7.2 insures a higher concentration of the hydroxyl radical scavenger HPO4-2 for a given H3PO4 concentration for stabilization of the dissolved ozone concentration and a corresponding higher rate of removal of organic materials such as photoresist. Accordingly, a pH of the order of 7.8 to 8.3 can provide for low copper etch rate (low copper corrosion) and a high photoresist etch rate (high resist strip rate). See Table 5 and the referenced E-pH diagrams.
CH3COOH Containing Compositions: In compositions containing CH3COOH (10 mM/L for example), and a weak acid such a CO2 or H3PO4 for pH buffering, operation at a pH within one pH unit of the pKa for H2CO3 of 6.3 or the pKa for the dissociation of H2PO4-1 to HPO4-2 of 7.2 can provide for good buffering against pH changes, better process control, and a wider process window. Operation at a pH above the pKa of 4.75 insures a higher concentration of the hydroxyl radical scavenger CH3COO-1 for a given CH3COOH concentration for stabilization of the dissolved ozone concentration and a corresponding higher rate of removal of organic materials such as photoresist. Accordingly, a pH between 6.3 and 8.3 can provide for low copper etch rate (low copper corrosion) and a high photoresist etch rate (high resist strip rate). See Table 5 and the referenced E-pH diagrams.
pH range for Cu2O3 protective layer formation: The pH can be in the range of 6 to 8.5, and the optimum pH value for the formation of a passivating protective layer on copper and for low copper corrosion is believed to be in the region of for stable Cu2O3 formation. The TMAH concentration is adjusted to achieve the target pH value. With a potential of approximately 1300 mV to 1000 mV (with respect to SHE), a dissolved CO2 concentration of approximately 5 millimoles/liter, and a dissolved copper concentration of 1.0 E-2 millimoles/liter, the pH range for stable Cu2O3 formation is from a pH of approximately 6.0 to a pH of approximately 8.5. With a potential of approximately 1300 mV to 1000 mV (with respect to SHE), a dissolved CO2 concentration of approximately 16 millimoles/liter, and a dissolved copper concentration of 1.0 E-2 millimoles/liter, the pH range for stable Cu2O3 formation is from a pH of approximately 6.0 to a pH of approximately 8.5. See Table 5 and the referenced E-pH diagrams for a complete summary of the results.
Nominal Concentrations: In compositions containing (O3, H2O, CO2 and TMAH), (O3, H2O, CO2, H3PO4, and TMAH), (O3, H2O, H3PO4 and TMAH), (O3, H2O, CH3COOH, and TMAH), (O3, H2O, CO2, CH3COOH, and TMAH), (O3, H2O, CH3COOH, H3PO4, and TMAH) or (O3, H2O, CO2, CH3COOH, H3PO4, and TMAH)) the dissolved CO2 concentration can be in the range of approximately 1 to 20 millimoles/liter, the H3PO4 and CH3COOH or other weak carboxylic acid concentration can be in the range of approximately 1 to 20 millimoles/liter, and the dissolved ozone concentration can be in the range of 1 to 200 mg/L. The dissolved ozone concentration is more preferably in the range of 25 to 200 mg/L dissolved ozone concentration so as to maintain high values for the ORP of the solution with respect to the standard hydrogen electrode that place the operating point in the region for Copper Sesquioxide (Cu2O3) formation on the relevant E-pH diagram. See Table 5 and the referenced E-pH diagrams.

In Table 5 we present a summary of results on the calculated pH range for Cu2O3 protective film formation. This was determined from the intersection of the experimentally established ORP-pH regression line for ozone dissolved in water with E-pH diagram for selected Cu—H2O-additive systems. The optimal operating pH is chosen for maximum overpotential, good pH buffering, good HO radical scavenger species formation for high resist etch rate and protective film formation and low copper etch rate.

TABLE 5
Calculated pH range for Cu2O3 protective film formation - Determined from the
intersection of the experimentally established ORP-pH regression line for ozone
dissolved in water with E-pH diagram for selected Cu—H2O-additive systems;
optimal operating pH chosen for maximum overpotential, good pH buffering,
good HO radical scavenger species formation, high resist etch rate, and low
copper etch rate.

| | | | | | | pH | pH | |
|---|---|---|---|---|---|---|---|---|
| System | | pH min | pH min | | | optimal | max | |
| Total Dissolved | T | @zero | @full | | | operating | Eh | |
| Cu Conc. = 10−2 mM | (° C.) | overpotential | overpotential | pKa | pKa + 1 | range | fall | FIG. |
| Cu—H2O—CO2 | 42 | 5.2 | 7.3 | 6.3 | 7.3 | 6.8 ± 0.5 | 8.5 | |
| (5 mM) | | | | | | | | |
| Cu—H2O—CO2 | 53 | 5.1 | 7.1 | 6.3 | 7.3 | 6.8 ± 0.5 | 8.5 | |
| (5 mM) | | | | | | | | |
| Cu—H2O—CO2 | 42 | 5.2 | 7.8 | 6.3 | 7.3 | 6.8 ± 0.5 | 8.5 | |
| (16 mM) | | | | | | | | |
| Cu—H2O—CO2 | 53 | 5.0 | 7.6 | 6.3 | 7.3 | 6.8 ± 0.5 | 8.5 | |
| (16 mM) | | | | | | | | |
| Cu—H2O—H3PO4 | 42 | 6.0 | 7.8 | 7.2 | 8.2 | 8.0 ± 0.25 | 8.5 | |
| (10 mM) | | | | | | | | |
| Cu—H2O—H3PO4 | 53 | 5.9 | 7.8 | 7.2 | 8.2 | 8.0 ± 0.25 | 8.5 | |
| (10 mM) | | | | | | | | |
| Cu—H2O—CH3COOH | 42 | 5.4 | 6.2 | 4.75 | 5.75 | NA | 8.5 | |
| (10 mM) | | | | | | | | |
| Cu—H2O—CH3COOH | 53 | 5.2 | 6.1 | 4.75 | 5.75 | NA | 8.5 | |
| (10 mM) | | | | | | | | |
| Cu—H2O—CH3COOH | 42 | 5.3 | 6.1 | 4.75 | 5.75 | NA | 8.5 | |
| (5 mM) | | | | | | | | |
| Cu—H2O—CH3COOH | 53 | 5.2 | 6.0 | 4.75 | 5.75 | NA | 8.5 | |
| (5 mM) | | | | | | | | |
| Cu—H2O | 42 | 5.3 | 6.1 | NA | NA | NA | 8.5 | |
| Cu—H2O | 53 | 5.2 | 6.0 | NA | NA | NA | 8.5 | |
| Cu—H2O—H3PO4 | 42 | 6.0 | 7.8 | 7.2 | 8.2 | 8.0 ± 0.25 | 8.5 | |
| (10 mM)—CO2 | | | | | | | | |
| (5 mM) | | | | | | | | |
| Cu—H2O—H3PO4 | 53 | 5.9 | 7.8 | 7.2 | 8.2 | 8.0 ± 0.25 | 8.5 | |
| (10 mM)—CO2 | | | | | | | | |
| (5 mM) | | | | | | | | |
| Cu—H2O— | 42 | 5.2 | 7.3 | 6.3 | 7.3 | 6.8 ± 0.5 | 8.5 | |
| CH3COOH (5 mM)—CO2 | | | | | | | | |
| (5 mM) | | | | | | | | |
| Cu—H2O— | 53 | 5.1 | 7.1 | 6.3 | 7.3 | 6.8 ± 0.5 | 8.5 | |
| CH3COOH (5 mM)—CO2 | | | | | | | | |
| (5 mM) | | | | | | | | |
| Cu—H2O— | 42 | 6.0 | 7.6 | 7.2 | 8.2 | 8.0 ± 0.25 | 8.5 | |
| CH3COOH | | | | | | | | |
| (5 mM)—H3PO4 | | | | | | | | |
| (5 mM) | | | | | | | | |
| Cu—H2O— | 53 | 5.9 | 7.6 | 7.2 | 8.2 | 8.0 ± 0.25 | 8.5 | |
| CH3COOH (5 mM)—H3PO4 | | | | | | | | |
| (5 mM) | | | | | | | | |

In Table 6 below, we present a summary of measured and predicted results for the Cu—H2O—CO2 system for 5 mM/L & 16 mM/L dissolved CO2 concentration. Since the pH for the test was greater than pKa+1=7.3 and therefore outside of the buffer range, the pH control was poor and the pH may have been above pH 8.5 or pH 9.0 for some of the tests runs; the probable phase formed based upon the measured Cu etch rate is shown underlined. We can see that a protective layer with CuO protects the copper to a certain degree. Here, formation of a duplex protective layer such as Cu2O/CuO could be responsible for the observed passivation. Cu corrosion rate with around 50 A/min could be assigned to this case. However, if a protective layer with Cu2O3 is established, copper corrosion rate is much lower. The significant decrease in the copper corrosion rate in this case is probably due to the formation of a triplex passivating layer such as Cu2O/CuO/Cu2O3 on the copper surface.

TABLE 6
Carbonate System - Summary of Measured and Predicted Results for 5 mM/L &
16 mM/L dissolved CO2 concentration; since the pH for the test was greater than
pKa + 1 = 7.3 and therefore outside of the buffer range, the pH control
was poor and the pH may have been above pH 8.5 or pH 9.0 for some of the
tests runs; the probable phase formed based upon the measured Cu etch rate is
underlined

| | | | | | Predicted | | |
|---|---|---|---|---|---|---|---|
| | | | | | | predicted | |
| Dissolved | Dis- | | | | | solid phase | |
| CO2 | solved | Measured | | | pH | in optimum | |
| Concentration; | Copper | pH | predicted | Meas. Cu | optimum | pH | E-pH |
| Process | Conc. | for | solid | Etch Rate | operating | operating | Figure |
| Temperature | mM/L | test | phase | A°/min | range | range | Number |
| 5 mM CO2; | 1E−2 | 8.32+ | Cu2O3 | ˜50 | 6.8 ± 0.5 | Cu2O3 | |
| Temp: 42° C.; | | | or | | | | |
| Comparative | | | CuO | | | | |
| Example 4 | | | | | | | |
| 16 mM CO2; | 1E−2 | 8.35+ | Cu2O3 | ˜10 | 6.8 ± 0.5 | Cu2O3 | |
| Temp: 42° C.; | | | or | | | | |
| Comparative | | | CuO | | | | |
| Example 5 | | | | | | | |

In Table 7 below we present a summary of measured and predicted results for the Cu—H2O—CO2—H3PO4 system for a 5 mM CO2 concentration and 10 mM H3PO4 concentration. Since the pH for the test was within one pH unit of the pKa of 7.2 (for the dissociation of H2PO4-1 to HPO4-2), i.e. between 6.2 and 8.2, the pH was within the buffer range and the pH control was good.

TABLE 7
Carbonate/Phosphate System - Summary of Measured and Predicted Results for 5 mM/L
CO2 + 10 mM/L H3PO4; since the pH for the test was within one pH unit of the pKa for H3PO4 of
7.2, i.e. between 6.2 and 8.2, the pH was within the buffer range and the pH control was good.

| | | | | | Predicted | | |
|---|---|---|---|---|---|---|---|
| Dissolved CO2 | | Measured | | | | predicted | |
| Concentration and | | | | Meas. | | solid phase | |
| H3PO4 | Dissolved | | | Cu | pH | in optimum | |
| Concentration; | Copper | pH | predicted | Etch | optimum | pH | E-pH |
| Process | Conc. | for | solid | Rate | operating | operating | Figure |
| Temperature | mM/L | test | phase | A°/min | range | range | Number |
| 5 mM CO2 + 10 mM | 1E−2 | 7.67 | Cu2O3 | ˜7 | 8.0 ± 0.25 | Cu2O3 | |
| H3PO4; Temp: 42 C. | | | | | | | |
| Comparative | | | | | | | |
| Example 6 | | | | | | | |
| 5 mM CO2 + 10 mM | 1E−2 | 7.65 | Cu2O3 | ˜8 | 8.0 ± 0.25 | Cu2O3 | |
| H3PO4; Temp: 53 C. | | | | | | | |
| Comparative | | | | | | | |
| Example 7 | | | | | | | |

Under the Condition 5, the E-pH diagrams (see FIG. 1a-6b) predict the formation of Cu2O3 on the copper surface during the Process A. The significantly low copper corrosion rate observed in this case is likely to be due to the formation of a triplex passivating layer such as Cu2O/CuO/Cu2O3 on the copper surface. We can see that a protective layer with Cu2O3 is likely to be more protective than CuO and the copper corrosion rate is likely to be lower.

5.4 Surface Treatment Compositions—Summary:

One can formulate ozone-water based treatment solutions for corrosion free cleaning and/or surface treatment of a material including surface treatment for the formation of a protective layer or barrier layer on a material according to the invention using the formulations outlined in Table 8 below:

TABLE 8
Treatment solution compositions for corrosion free treatment of a substrate
comprising ozone gas and, in some cases carbon dioxide gas, dissolved in a
solvent with a predetermined dissolved ozone concentration, and predetermined
dissolved CO2 concentration with predetermined concentrations of H3PO4,
CH3COOH, and/or at least one weak carboxylic acid, with a sufficient amount
of ammonia free base (base not containing NH3 OR NH4+) added to adjust
the pH to a predetermined value as summarized below.

| | Solvent | | Gas 2 | | | Base |
|---|---|---|---|---|---|---|
| NAME | note 1 | Gas 1 | note 3 | Acid 1 | Acid 2 | note 2 |
| 1. CO2 ONLY | H2O | O3 | CO2 | NA | NA | TMAH |
| 2. CO2 AND H3PO4 | H2O | O3 | CO2 | H3PO4 | NA | TMAH |
| 3. H3PO4 ONLY | H2O | O3 | NA | H3PO4 | NA | TMAH |
| 4. CH3COOH ONLY | H2O | O3 | NA | CH3COOH | NA | TMAH |
| 5. CO2 AND CH3COOH | H2O | O3 | CO2 | CH3COOH | NA | TMAH |
| 6. CO2 AND CH3COOH and | H2O | O3 | NA | CH3COOH | NA | TMAH |
| H3PO4 | | | | | | |
| 7. CH3COOH AND H3PO4 | H2O | O3 | NA | CH3COOH | H3PO4 | TMAH |
| 8. AT LEAST ONE WEAK | H2O | O3 | NA | at least one | NA | TMAH |
| CARBOXYLIC ACID | | | | weak | | |
| | | | | carboxylic | | |
| | | | | acid | | |
| 9. AT LEAST ONE WEAK | H2O | O3 | NA | at least one | H3PO4 | TMAH |
| CARBOXYLIC ACID AND | | | | weak | | |
| H3PO4 | | | | carboxylic | | |
| | | | | acid | | |
| 10. CO2 AND AT LEAST | H2O | O3 | CO2 | at least one | NA | TMAH |
| ONE WEAK CARBOXYLIC | | | | weak | | |
| ACID | | | | carboxylic | | |
| | | | | acid | | |

note 1: solvent into which ozone gas may be dissolved; one example is H2O
note 2: sufficient amount of ammonia free base (base not containing NH3 OR NH4+) (not containing any species that form soluble complexes with copper) added to adjust the pH to a predetermined value; one example is TMAH
note 3: CO2 gas is a source of acid - carbonic acid (H2CO3)

In the preferred embodiments for the above examples 8, 9, or 10, the weak carboxylic acid is typically selected from the group consisting of formic(methanoic) acid, propanoic (propionic) acid, butanoic (butyric) acid, pentanoic(valeric) acid, hexanoic(caproic) acid, heptanoic (enanthic) acid, actanoic(caprylic) acid, nonanoic(pelargonic) acid and decanoic(capric) acid.

Also in the above examples 1-10, the substrate in the preferred embodiments typically is comprised at least in part of copper or a copper-based alloy, or in another embodiment is a semiconductor or other electronic device substrate. In other embodiments for examples 1-10, the substrate is comprised at least in part of aluminum or an aluminum-based alloy, and in other embodiments, the substrate is comprised at least in part of at least one material selected from group consisting of tungsten, tungsten nitride, tantalum, tantalum nitride, cobalt, cobalt-tungsten-phosphide, silicon, silicon nitride, silicon carbide, ruthenium, and hafnium. In yet other embodiments for examples 1-10, the substrate is comprised at least in part of at least one material selected from the group consisting of zirconium, vanadium, chromium, molybdenum, nickel, and silver.

Also, in all of the examples 1-10, the solvent in the preferred embodiments is water.

In preferred embodiments of examples 1-10 above, the ammonia-free base is the strong metal-ion-free base TMAH (tetramethylammonium hydroxide). In other preferred embodiments of examples 1-10, the ammonia free base more generally contains one or more constituents selected from the group consisting of tetramethylammonium hydroxide, tetraethylammonium hydroxide, tetrapropylammonium hydroxide, tetrabutylammonium hydroxide. In yet other preferred embodiments it contains one or more constituents selected from the group consisting of tetraalkyl ammonium hydroxides. In yet other preferred embodiments, the ammonia free base contains one or more constituents selected from the group consisting of quaternary ammonium hydroxides. In other preferred modes, one may use a salt instead of a base. The preferred salts include quaternary ammonium carbonate, bicarbonate, phosphate, and acetate salts, including but not limited to tetraalkyl ammonium carbonates, tetraalkyl ammonium bicarbonates, tetraalkyl phosphates, tetraalkyl ammonium acetates, and other salts of weak carboxylic acids. In still other embodiments, salts could be selected from the group consisting of quaternary ammonium molybdate, chromate, dichromate, silicate, vandate, and borate salts, including but not limited to tetraalkyl ammonium molybdates, tetraalkyl ammonium chromates, tetraalkyl ammonium dichromates, tetraalkyl ammonium silicates, tetraalkyl ammonium vandate and tetraalkyl ammonium borates. The quaternary ammonium silicates are a preferred class of salts within this latter group because they are environmentally benign and lower cost as compared to the molybdates, chromates, dichromates, and vanadates.

In preferred embodiments for examples 1-10 above, the pH of the compositions is within the region of the E-pH diagram for the Cu—H2O based system for the formation of copper sesquioxide (Cu2O3). In other preferred embodiments for examples 1-10 above, the pH of the compositions and the oxidation-reduction potential with respect to the standard hydrogen electrode of said compositions are within the region of the E-pH diagram for the Cu—H2 based system for the formation of copper sesquioxide (Cu2O3). In other embodiments of examples 1-10, the pH is in the range of approximately 6 to 8.5. In other embodiments for examples 1-10, the pH is in the range of approximately 6. 3 to 7.3. In another embodiment, the pH is in the range of approximately 7.7 to 8.2.

In preferred embodiments of examples 1, 5, or 10, the compositions have a CO2 concentration in the range of approximately 1 to 20 millimoles/liter. Also, in the preferred embodiments of examples 2, 3, 6, 7, or 9, the H3PO4 concentration is in the range of approximately 1 to 20 millimoles/liter. Similarly, in the preferred embodiments for examples 4, 5, 6, or 7, the CH3COOH concentration is in the range of approximately 1 to 20 millimoles/liter. Furthermore, in the general cases of examples 8, 9, or 10, the compositions in the preferred embodiments has a total concentration of the weak carboxylic acids is in the range of approximately 1 to 20 millimoles/liter.

In preferred embodiments of examples 1-10, the dissolved ozone concentration is in the range of approximately 25 to 200 mg/L. In other preferred embodiments of examples 1-10, the dissolved ozone concentration is in the range of approximately 1 to 200 mg/L.

In preferred embodiments for examples 1-10, the oxidation-reduction potential with respect to the standard hydrogen electrode of the various compositions is greater than or equal to approximately 1100 mV. In other preferred embodiments for examples 1-10, the oxidation-reduction potential with respect to the standard hydrogen electrode of the various compositions is in the range of approximately 1100 mV to 1300 mV. In yet other preferred embodiments for examples 1-10, the oxidation-reduction potential with respect to the standard hydrogen electrode of the compositions is in the range of approximately 1 100 mV to 1200 mV.

In preferred embodiments for examples 1-10, the temperature of the compositions at the point of reaction with the substrate material is in the range of 5° C. to 95° C. In other preferred embodiments for examples 1-10, the temperature of the compositions at the point reaction with the material is in the range of 35° C. to 65° C.

5.5 Features and Benefits of Representative Chemicals in Treatment Compositions

5.5.1 Ozone (O3) Gas Dissolved in Water

Source of Strong Oxidizer for Cleaning and Surface Treatment
Environmentally Benign Chemistry
Created and Destroyed at the Point of Use
Low Cost Chemical—Formed from Oxygen Gas and DI water
Specific Oxidizer—Damage free Treatment of CVD low K dielectrics
   5.5.2 H3PO4, CH3COOH, or CO2 dissolved in H2O to form H2CO3
low-cost, non-hazardous chemical, readily available, semiconductor grade
chemical already available in the semiconductor fabrication facility
ozone compatible chemical
   5.5.3 H3PO4
source of phosphate ions such as HPO4-2 for stabilizing dissolved ozone concentration at the surface of the substrate and higher photoresist removal rate, higher organic residue removal rate, material oxidation rate, material treatment rate, or material cleaning rate
a weak acid and pH buffer for pH control with a pKa=7.2 for the dissociation of H2PO4-1 to HPO4-2 and good buffering in the pH range of pKa±1.0
source of PO4-3 for passivating film formation under some conditions
   5.5.4 CH3COOH
source of CH3COO-1 for stabilizing dissolved ozone concentration at the surface of the substrate and higher photoresist removal rate, higher organic residue removal rate, material oxidation rate, material treatment rate, or material cleaning rate
a weak acid and pH buffer for pH control with a pKa=4.75 and good buffering in the pH range of pKa±1.0
   5.5.5 CO2 Gas Dissolved in H2O to Form H2CO3
source of HCO3-1 and CO3-2 for stabilizing dissolved ozone concentration in ozone-water solution supply and higher dissolved ozone concentration
source of HCO3-1 and CO3-2 for stabilizing dissolved ozone concentration at the surface of the substrate and higher photoresist removal rate, higher organic residue removal rate, material oxidation rate, material treatment rate, or material cleaning rate
a weak acid and pH buffer for pH control with a pKa=6.3 and good buffering in the pH range of pKa±1.0
source of HCO3-1 and CO3-2 for passivating film formation under some conditions
   5.5.6 Tetramethylammonium Hydroxide (TMAH)
strong base for pH adjustment
metal-ion-free base
ammonia (NH3 OR NH4+) free base—does not form soluble complexes with copper
low-cost, non-hazardous chemical, readily available, semiconductor grade
chemical already available in the semiconductor fabrication facility—used as photoresist developer
compatible with dissolved ozone

5.6 Buffer Formulations with Representative Chemicals in Treatment Compositions

5.6.1 pH Buffer Formulations—Carbonate Based:

If the weak acid carbonic acid is titrated with a strong base such as TMAH to a pH which is within one pH unit of the pKa of 6.3, then the solution will have a relatively good buffer capacity within a pH region which is one pH unit above or below the pKa.

5.6.2 pH Buffer Formulations—Phosphate Based:

If the weak acid phosphoric acid is titrated with a strong base such as TMAH to a pH which is within one pH unit of the pKa of 7.2 (for the dissociation of H2PO4-1 to HPO4-2), then the solution will have a relatively good buffer capacity within a pH region which is one pH unit above or below the pKa.

5.7 pH and the Formation of Stable Protective Films:

See Tables 2a-6b, associated discussion of tables, and other teaching in this application.

5.8 Hydroxyl Radical Scavenging with Representative Chemicals in Treatment Compositions

5.8.1 pH and Hydroxyl Radical Scavenging—Carbonate, Phosphate, or Acetate Based:

When CO2 is dissolved in water carbonic acid (H2CO3) forms. Carbonic acid is a weak acid which dissociates into H+ and HCO3-1. When the pH is set to 1 pH unit above the pKa, then the concentration of HCO3-1 is 10 times that of CO2. This provides a higher level of OH radical scavenging for a given dissolved CO2 concentration than for the case of pH=pKa.

Phosphoric acid is a weak acid which partially dissociates into H+ and H2PO4-1. H2PO4-1 can further partially dissociate into H+ and HPO4-2. The pKa for the dissociation of H2PO4-1 to H+ and HPO4-2 is 7.2. When the pH is set to 1 pH unit above the pKa for this dissociation, then the concentration of HPO4-2 is 10 times that of H2PO4-1. This provides a higher level of OH radical scavenging for a given H3PO4 concentration than for the case of pH=pKa.

Acetic acid is a weak acid which partially dissociates into H+ and CH3COO-1. The pKa for the dissociation of H+ and CH3COO-1 is 4.75. When the pH is set to 1 pH unit above the pKa for this dissociation, then the concentration of CH3COO-1 is 10 times that of CH3COOH. This provides a higher level of OH radical scavenging for a given CH3COOH concentration than for the case of pH=pKa.

Hydroxyl radical scavengers such as carbonates and phosphates and acetates and other carboxylic acids assist in the stabilization of the dissolved ozone concentration and a higher photoresist etch rate, higher cleaning rate, or higher surface treatment rate. The pH is can be set in a region to not only provide for good pH buffering and good OH radical scavenging, but also to provide for the formation of a protective passivating film on exposed copper or aluminum surfaces and a very low copper etch (corrosion) rate

5.8.2 pH and Hydroxyl Radical Scavenging—Other Weak Carboxylic Acids

Other weak carboxylic acids such as formic(methanoic) acid, propanoic (propionic) acid, butanoic (butyric) acid, pentanoic(valeric) acid, hexanoic(caproic) acid, heptanoic (enanthic) acid, actanoic(caprylic) acid, nonanoic(pelargonic) acid and decanoic(capric) acid and salts of these carboxylic acids could also be used to stabilize dissolved ozone and to achieve higher photoresist etch rates outlined here.

5.9 Base Selection

Any suitable base not containing ammonia (NH4+ or NH3) or other species that form soluble complexes with copper may be used in the compositions of the present invention. The bases are preferably quaternary ammonium hydroxides such as tetraalkyl ammonium hydroxides. The most preferable of these materials is tetramethylammonium hydroxide (TMAH). Other bases containing metal ions such as sodium or potassium may also be operative, but are not preferred because of the possible residual metal contamination that could occur.

5.10 Protective Layers with Thickness which can be Self Limiting

As discussed above, a solid phase layer or layer structure selected from the group consisting of Cu2O3, malachite, a copper phosphate, the triplex passive layer structure Cu2O/CuO/Cu2O3, the triplex passive layer structure Cu2O/malachite/Cu2O3, and the triplex passive layer structure Cu2O/a copper phosphate/Cu2O3 is believed to form when one or more of the preferred compositions is applied to copper or a copper-containing material or alloy for a specified duration. The layer or layer structure formed with the inventive compositions disclosed herein can be protective and, accordingly, the thickness of the layer or layer structure does not increase without limit as the time of exposure to the treatment composition is increased. The thickness of the protective layer or layer structure is self limiting with a typical maximum thickness less than about 100 Angstroms. This is in contrast to the case of a non-protective Cu2O or CuO layer that may form on copper in which the growth in layer thickness is not self-limiting.

### 6 SURFACE TREATMENT METHODS AND APPARATUS

6.1 The present invention relates in part to a method and apparatus for treating materials such as copper, aluminum, or copper or aluminum containing metal alloys, used in fabricating semiconductor devices with an ozone-solvent solution and avoiding damage to metals by corrosion. The treatment can be for one or more purposes including cleaning, material removal, formation of protective film or protective layer or protective barrier layer on metals such as copper and aluminum, oxidation of a material for the formation of an oxide layer or oxide film on a material such a silicon, removal of an organic material such as photoresist for applications such as FEOL(front-end-of-line) resist rework, FEOL post etch strip, FEOL post implant strip, BEOL (back-end-of-line) resist rework, and BEOL post etch strip, post CMP clean. The treatment can be used for removal of thin layers of organic contamination to promote film adhesion in pre-deposition cleaning applications or post CMP cleaning applications. This can be achieved by properly selecting the composition of the ozone solvent solution and controlling the pH of the ozone-solvent solution while avoiding the use of certain chemical constituents in the ozone solvent solution that can be damaging to copper or aluminum. A number of different methods and apparatus can be used as discussed above. We will present below several example methods for preparing the inventive treatment solution and several inventive methods of preparing and applying the treatment solution to materials such as semiconductor wafers as the like. There are a number of other methods preparing and applying treatment solutions to which the teaching of this invention can be applied as well. Some have been described earlier above and additional ones have been described in the applicants' previously filed patent applications.

6.2 Detailed Description of Method and Apparatus

Treatment Solution Preparation Method and Materials Processing Method and Apparatus Including Point-Of-Use Chemical Injection—Multiple Chemical Supplies—Description and Operation—FIG. 7a

With reference to FIG. 7a, oxygen gas supply 167 is connected through length of tubing to the inlet of ozone generator 170. The outlet of the ozone generator is connected to the gas inlet of gas-liquid contactor 145. The gas outlet of the gas-liquid contactor is connected to an ozone destruction unit 178. The excess ozone gas that is not dissolved into the liquid in the contactor exits from the contactor, and is converted to oxygen by the destruction unit. The outlet of ozone destruction is connected to the facility vent/exhaust 182. The ozone destruction unit can be of the catalytic type, thermal type, or any other type known to those skilled in the art. Carbon dioxide (CO2) gas supply 165 is connected to the gas inlet of ozone generator. The flow rates of the oxygen gas the CO2 gas determine the composition of the gas entering the ozone generator. The CO2 gas percentage in the mix can typically range from 500 ppm to 10% by volume. In another embodiment CO2 gas supply 163 can be added to inject additional CO2 gas into the gas inlet gas-liquid contactor 145. In another embodiment, provided that the ozone generator can operate with good performance with pure oxygen feed gas, the CO2 gas supply 165 can be eliminated and all CO2 gas can be supplied to the contactor by the directly connected CO2 supply 163. Oxygen gas supply 167 and CO2 gas supplies 163 and 165 each include a pressure regulator and flow controller for setting the flow rate and feed pressure of each gas. In any case the amount of ozone gas and CO2 gas that is dissolved in the DI water as the water passes through the contactor is dependent upon the total partial pressure of the ozone gas and the total partial pressure of the CO2 gas in the contactor and the temperature of the water. In one embodiment the DI water can be supplied at ambient temperature of 25 degree C. for example. In another embodiment, the DI water supply 130 can additionally include a heat exchanger (not shown) for chilling the DI water to a below ambient temperature of 5 or 10 degree C. for example. Ozone generator 170, gas-liquid contactor 145, and ozone destruction unit 178 comprise the major components of a typical ozone-water solution supply. The ozone water solution supply 22 comprising these components is denoted in FIG. 7a.

With reference to FIG. 7a, pressurized DI water supply 130 is connected through a length of tubing to the liquid inlet port of gas-liquid contactor 145. Contactor 145 can be a hydrophobic membrane contactor, a venturi injector and bubble column contactor, a packed column contactor, or other gas-liquid contactor known to those skilled in the art. The ozone gas and CO2 can be dissolved at atmospheric pressure (˜1 bar) or at elevated pressures above atmospheric pressure. The ozone gas and CO2 gas can be dissolved at ambient temperature, or at sub-ambient temperature where the solubility, as predicted by Henry's Law, is higher. The contactor provides for a large interfacial surface area between the gas and the liquid for efficient mass transfer for dissolving the gas into the liquid. Pressurized DI water supply 130 typically comprises a pressurized source of DI water connected though a liquid pressure regulator and a liquid flow controller and liquid particulate filter. The liquid outlet port of gas-liquid contactor 145 is connected through a length of tubing to the common input of a three-way valve 24. The one outlet of three-way valve 24 is connected through a length of tubing to one inlet of injection “T” 40. The other outlet of three-way valve 24 is connected through a length of tubing to the facility drain-reclaim 26 for the ozone-water solution. The outlet of injection “T” 40 is connected to the inlet of mixer 41-2. The mixer 41-2 can a static mixer or other mixing device known to those skilled in the art. In an alternative embodiment, the injection and mixing function of the injection “T” 40 and mixer 41-2 can be replaced by a venturi injector. In this embodiment, the higher flow rate main flow is connected to the motive flow inlet of the venturi and the lower flow rate injected chemical connected to the suction port of the venturi. The outlet of chemical injector-mixer 41-2 is connected to the common inlet port of three-way valve 32. The one outlet of three-way valve 32 is connected through a short length of tubing to dispense nozzle 36 positioned to supply the treatment solution for treatment of material 38. The other outlet of three-way valve 32 is connected through a length of tubing to the facility drain-reclaim 34 for the heated ozone-water solution.

With reference to FIG. 7a, the outlet of an injected chemical supply 42-1, containing TMAH for example, is connected to the inlet of two-way valve 44-1. The outlet of valve 44-1 is connected to a first chemical injection port of a multiple port chemical injection manifold 45. The outlet of an injected chemical supply 42-2, containing H3PO4 for example, is connected to the inlet of two-way valve 44-2. The outlet of valve 44-2 is connected to a second to a first chemical injection port of a multiple port chemical injection manifold 45. The outlet of injection manifold 45 is connected to the inlet of mixer 41-1. The outlet of mixer 41-1 is connected to one inlet the injection “T” 40 located upstream of mixer 41-2. This configuration provides for mixing the injected chemicals prior to injecting and mixing them with the main flow comprising the ozone-water-CO2 solution that is connected to the other inlet of the injection “T” located upstream of mixer 41-2. In an alternative embodiment, the mixer 41-1 could be eliminated and all mixing could occur in mixer 41-2. Chemicals in gaseous form can be dissolved in solution or chemicals can be injected in liquid form. For example, CO2 gas can be dissolved in water to form the weak acid H2CO3 (carbonic acid) and the ammonia-free, metal-ion-free strong base TMAH (tetramethylammonium hydroxide) and the weak acid H3PO4 can be injected and mixed. The pH of the final solution is determined by the concentration of the acid and base. The control of the solution pH is one component in the formation of a corrosion free treatment composition as discussed herein. The inventors have discovered that the order of introduction of acid and bases into an ozone-water solution can be critical. If a strong base such as TMAH is introduced into an ozone-water solution prior to the introduction of the acid, then the pH can be driven to very high values (pH 10 or higher for example) where the dissolved ozone concentration in the ozone-water solution can quickly decay to low levels. The inventors have found that it is critical that the chemicals be injected in such a way as to avoid shifting the pH of the ozone-water solution to a high level where the rate of ozone decomposition is high. One approach is to first introduce the acid and then introduce the base. This approach can be used in the case of CO2 injection followed by TMAH injection. Given a predetermined dissolved CO2 concentration, the volume flow rate of the TMAH is adjusted to achieve a predetermined pH for passivating film formation. Another approach is to introduce the acid and the base together, mix the acid and base, and then inject the mixture into the ozone-water solution. This latter approach can be used when the acid and base are both liquid chemicals. A combination approach can be used when a gaseous chemical and two or more liquid chemicals are introduced into an ozone-solvent solution. For example, first dissolving into the ozone-water solution a gaseous chemical such as CO2 gas, premixing two additional liquid chemicals such as TMAH and H3PO4, and then injecting and mixing the mixed liquid chemicals into the ozone-water solution. Given a predetermined dissolved CO2 concentration (5 to 10 mM/L for example) and predetermined H3PO4 concentration (10 mM/L for example), the volume flow rate of the TMAH is adjusted to achieve a predetermined pH for passivating film formation. Embodiments for the injection of chemicals, either from a fewer number, or from a greater number of injected chemical supplies, can be implemented using approaches similar to those described herein. (In general we can consider not just ozone-water solutions but ozone-solvent solutions where water is one of many possible solvents.)

The injected chemical supplies 42-1 and 42-2 provide a chemical at a predetermined delivery pressure and a predetermined flow rate into the injection ports of the injection manifold 45 connected to mixer 41-1. The concentration of the chemical dispensed by the supply and ratio of the flow rate of the injected chemical to the flow rate of the ozone-gas-water solution through the injector/mixer determines the concentration of the injected chemical in the solution exiting from the mixer. For example, if the total flow rate of the ozone-water-injected chemicals solution is 2 L/min (33.3 ml/sec), and the flow rate of an injected chemical is 1 ml/sec, then the injected chemical will be diluted by a factor of 33.3. Accordingly, if an injected chemical reservoir contains a chemical at a concentration of 333 millimoles/liter, then the final concentration of the injected and mixed chemical will be 10 millimoles/liter. The design of pressurized chemical supplies is well known to those skilled in the art. Each of the chemical supplies 42-1 and 42-2 may be implemented with a source of pressurized nitrogen regulated to a predetermined pressure (not shown) connected through a length of tubing to a respective reservoir (not shown) containing a liquid chemical to be injected. The dip-tube outlet (not shown) of each chemical reservoir is connected through a length of tubing to the inlet side a flow controlling needle valve (not shown). The outlet of the each flow controlling needle valve is connected through a length of tubing to the inlet of each flow meter (not shown). The outlet of each flow meter is connected through a length of tubing to the inlet of each chemical injection control valve 44-1 or 44-2. The outlet of each chemical injection control valve 44-1 and 44-2 is connected through a length of tubing to the chemical injection port of chemical injector/mixer 41-1. Each pressurized injected chemical supply can also be implemented using a metering pump of other means known to those skilled in the art.

Point-of-use Chemical Injector: The chemical injector/mixer may be a venturi injector, a “T” coupled to the inlet of a static mixer, or other device known to those skilled in the art. Each injected chemical supply must deliver its chemical to the injection port of chemical injector/mixer with sufficient pressure to achieve the desired predetermined injected chemical flow rate. The internal volume of the injector mixer 41-2 can be kept small to minimize the transit time of the chemical solution through the injector to the point of use.

Timed and Sequenced Chemical Injection: These embodiments may provided for the injection of different chemicals at predetermined times during the materials processing cycle. The rate of injection for each of the chemicals can be specified and controlled for each instant of time during the materials processing cycle. A preferred embodiment may utilize a computer or microprocessor to control the flow rates at each time step of the process.

Process Instrumentation:

A dissolved ozone monitor and temperature sensor may be inserted in the short length of tubing just upstream of the dispense nozzle 36. This instrumentation provides a continuous readout of the dissolved ozone concentration and temperature of the ozone-water solution just upstream of the dispense point. This can be a source of useful diagnostic information during process development and in a production environment. A pH probe for measuring the pH of the dispensed chemistry and an ORP probe for measuring the oxidation-reduction potential of the dispensed chemistry can also be incorporated. In one embodiment small internal volume flow through cells for the pH and ORP probes can be placed in the dispense line just upstream of the dispense nozzle. In another embodiment one or both of these instruments can be placed in the purge line connected between the purge outlet of three way valve 32 and the drain/reclaim to provide a confirmation of the pH and ORP of the chemistry at the start of each processing cycle while not placing the instrumentation in the process flow line. This design reduces the potential for process contamination and also provides for maintenance of the instruments without disturbing the process. In another embodiment, the dissolved ozone-monitor and/or the temperature sensor can be placed in the purge line.

Purge prior to Dispense: A purge cycle of 5 to 10 seconds prior to each dispense cycle, controlled by dispense/purge valve 32, serves to flush the internal volume of the tubing and other components and insure that the chemical composition is at steady state and meets specifications prior to each dispense cycle.

Means for Purging Chemical Injector Lines. In an alternative embodiment, each chemical injection valve 44-1, 44-2 may be a four-way valve to provide for purging the injection line. In the “off” position a four-way chemical injection valve can shut off chemical injection to the injected chemical inlet. In the “on” position, the valve can permit chemical injection to the injected chemical inlet. In the “purge” position permit the purging with DI water, for example, the lengths of tubing between the valves 44-1 and 44-2 and the chemical injector/mixer 41-1 to prepare for the introduction of a different chemical into the injected chemical inlet of chemical injector/mixer 41-1.

Alternative Processing Configurations: The material may be treated using a number of different materials processing configurations discussed elsewhere in this specification. These include, but are not limited to, single wafer spin processors, batch spin processors, single wafer immersion processors, batch immersion processors. The process module may be fitted with a suitable exhaust system for process off gases and suitable process liquid “drain” to direct the used process chemistry to a facility drain/reclaim system. The process chemistry may be used in a single pass configuration or in a circulating chemistry configuration. This invention can be implemented in a closed process chamber operating at 1 bar pressure in which the process chamber fully encloses the substrate during the processing cycle. This invention can be implemented in a closed process chamber operating at greater than 1 bar pressure in which the process chamber fully encloses the substrate during the processing cycle and provides for processing at pressures above 1 bar through the use of back pressure regulators at the outlet of the processing chamber. This invention can be implemented in an open process chamber in which the process chamber is at least partially open during at least a portion of the processing cycle and thereby does not fully enclose the wafer during at least a portion of the processing cycle. This invention can be implemented in a spin processing configuration such as shown in FIG. 8a. This invention can be implemented in an immersion processing configuration with the ozone-solvent solution flowing through the processing chamber that contains one or more substrates or materials to be processed. This invention can be implemented in a spray processing chamber in which the ozone solvent solution is sprayed onto the surface of the materials to be processed. Many example processing configurations are shown in the inventors previously filed patent applications. These processing configurations can be used in conjunction with any of the embodiments disclosed herein, including those shown in FIGS. 7a, 7b, 8a, and 8b.

Alternative Means for Applying Ozone-Solvent Solution to The Substrate: The application of the ozone-water-other chemicals solution to the surface or surfaces of the material to be processed can be accomplished in a number of different ways. The solution may be applied to one or more surfaces of the substrate. In the one embodiment the solution can be applied to the center of the wafer through a single solid stream nozzle 36 with an inside diameter of 4.5 mm, for example, positioned to apply a flow of solution to the wafer at the center. In a second embodiment the solution can successively applied to different positions between the center and edge of the wafer. In this second embodiment the ozone-water solution can be flowed through a nozzle that can be successively positioned at different locations from the center to the edge of the wafer or from the edge to the center of the wafer. The wafer RPM can be changed for each position of the nozzle to control the fluid mechanics (water velocity profile and water film thickness) on the surface of the wafer. The dwell time at each position can be controlled to reduce the radial variation in the etch rate or cleaning rate or treatment rate over the duration of the materials processing cycle. In a third embodiment the solution can be applied the surface of the wafer with multiple nozzles 36A, 36B, 36C, . . . (not shown). In a fourth embodiment one or more nozzles may be mounted on one or more rotating spray arms (not shown) positioned to apply the solution to one or more surfaces of the material to be oxidized. The ozone gas, water, and other chemicals solution can be applied to the surface or surfaces of the material to be processed by other means familiar to those skilled in the art including those processes in which ozone gas is introduced into the process chamber, the solution is introduction is introduced into the process chamber as a vapor or mist, and the final solution is formed in the vapor phase and on the substrate surface. Some example methods are presented in the section below titled Methods of Forming a Treatment Solution and Applying a Treatment Solution to a Material.

Other Chemical Comipositions Used with Apparatus: Other chemical compositions can be used with a similar apparatus. For example, in cases in which CO2 is not used, the CO2 supply and associated hardware can be eliminated. In other cases CO2 can be used in only very low ppm concentrations (500 ppm for example) suitable for proper operation of the ozone generator. In another example, in chemical compositions using more that two liquid chemicals, as in the case of compositions based upon the use of CH3COOH and H3PO4 and TMAH for example, then additional chemical injectors may be added to the apparatus with additional static mixers or other mixing elements added according to the teaching of this invention.

Treatment Solution Preparation Method and Apparatus and Materials Processing Method and Apparatus Including Point-Of-Use Chemical Injection—Multiple Chemical Supiplies with Point of Use Heating

Description and Operation—FIG. 7b. In another embodiment the method and apparatus may additionally include a means for heating the ozone-water solution just upstream of the point of use. With reference to FIG. 7b, a point of use heat exchanger 28 and circulating heating unit 30 are shown. The other components of this embodiment are similar to those shown in FIG. 7a. The exchanger is positioned between the outlet of valve 24 and the chemical injection T 40. The one outlet of three-way valve 24 is connected through a length of tubing to the cold process fluid inlet of a heat exchanger 28. The other outlet of three-way valve 24 is connected through a length of tubing to the facility drain-reclaim 26 for the ozone-water solution as in FIG. 7a. The heated working fluid outlet of a circulating heating unit 30 is connected through a length of tubing to the heated working fluid inlet of heat exchanger 28. The circulating heating unit may include a controller for controlling the temperature of the circulating heated working fluid. For the given exchanger design, the temperature of the heated process fluid at the outlet of the exchanger is determined by the temperature and flow rate of the working fluid and the temperature and flow rate of the process fluid entering the exchanger. The heated working fluid outlet of heat exchanger 28 is connected through a length of tubing to the working fluid return of circulating heating unit 30. The heated process fluid outlet of heat exchanger 28 is connected through a short length of tubing to the inlet of chemical injector/mixer comprising an injection “T” 40 and a mixer 41-2. The outlet of chemical mixer 41-2 is connected through a short length of tubing to the common inlet port of three-way valve 32. The one outlet of three-way valve 32 is connected through a short length of tubing to a dispense nozzle 36. The other numbered components shown in FIG. 7b are the same as the like numbered components in FIG. 7a.

In this embodiment, the ozone-water solution is quickly heated from a lower temperature to a higher temperature to form a supersaturated solution in which the dissolved ozone concentration at elevated temperature is much higher than that which could have been achieved had the ozone-water solution been formed at that elevated temperature where equilibrium solubility as determined by Henry's law is very low. In this embodiment it is beneficial to minimize the loss of ozone from solution as the ozone water solution is heated and mixed with additional chemicals. The loss can be minimized by minimizing the residence time of the process solution in transit from the inlet of exchanger 28 to the dispense nozzle at 36. The short residence time from the inlet of the point-of-use heater 28 to the point of application of the ozone-water-injected chemical solution to the material to be treated has two important benefits. For given flow rate, a short residence time is achieved by making the internal volume of the intervening tubing and components small. In one example embodiment constructed by the inventors the exchanger internal volume was 90 ml corresponding to a residence time of 2 secs at a flow rate of 45 ml/sec (2.7 L/min). In one example embodiment constructed by the inventors the exchanger internal volume was 45 ml corresponding to a residence time of 1 sec at a flow rate of 45 ml/sec (2.7 L/min). The internal volume of the interconnecting tubing was kept small by using Teflon Tubing with small ID (1.25 inch ID for example) and keeping tubing lengths short (12 to 24 inches for example). The internal volume of other intervening components such as the chemical mixers was also kept small as well. A short residence time minimizes the amount of time available for the dissolved ozone to fall much during the time required for the solution to pass through the element. A short residence time also minimizes the amount of time available for the ozone-water solution to react with the injected chemicals. If the chemicals react with the ozone-water solution, the reaction may not only consume ozone and reduce the dissolved ozone concentration, but also may consume some or all of the injected chemical.

Alternative methods of heating the ozone-solvent solution at the point of the use: In another embodiment the heat exchanger 28 may be replaced by a direct heater which may be heated by an number of means including resistance heating, induction heating, convection heating, microwave heating, or radiant heating. In another embodiment the heat exchanger 28 may be an injector or eductor with the relatively low temperature ozone-water solution entering the motive flow inlet, high purity steam formed from DI water introduced into the suction inlet, and the heated ozone water solution exiting from the injector or eductor outlet. In other embodiments, the ozone-solvent solution may be heating at least one of the ozone-solvent solution and the substrate as discussed in the inventor's other prior files applications incorporated herein by reference.

Minimizing temperature or Dissolved Ozone Concentration Changes Caused by the Injection of Chemicals: In one embodiment the chemical injection “T” 40 and mixer 41-2 is located downstream of the heat exchanger 28. The temperature of the ozone-water solution is set at a predetermined temperature which is in the range of 30 to 95 deg. C. In an example electronic device cleaning and processing embodiment the temperature may be 40 to 60 deg. C. If the temperature of the injected chemical is below the temperature of the ozone-water solution entering the injector, then the solution exiting from the heater will be below the temperature of the solution entering the point-of-use heater. The fall in temperature may be mitigated by minimizing the volume flow rate of the injected chemical relative to the volume flow rate of the ozone-water solution. In an alternative embodiment, the injected chemicals can be preheated to approximately the same temperature as the temperature of the ozone-water solution entering the chemical inject thereby eliminating any fall in temperature mentioned above. In another embodiment, the chemical injection “T” 40 and mixer 41-2 could be located just upstream of the heat exchanger 28. In this case the injected chemicals are heated with the ozone-water solution. However, the chemicals have a slightly longer time available to react with the ozone-water solution. In addition the exchanger wetted materials must then be compatible with the injected chemicals.

The rate loss of ozone from solution can also be reduced by reducing the driving force for loss from solution. The rate of loss from solution is lower if the pressure at the outlet of exchanger 28 is maintained above ambient pressure. This can be achieved through the use of a flow restriction at the dispense nozzle or just upstream of the dispense nozzle. This can be achieved by selecting nozzle 36 with a suitable orifice size or by inserting a flow restriction of suitable size just upstream of the dispense nozzle 36. A length of relatively small diameter tubing can also serve as a pressure-dropping element. The incorporation of a means for increasing the pressure (15 to 30 psig for example) just upstream of the dispense nozzle 36 can decrease the rate of loss of ozone gas from the heated solution compared to the case of letting the pressure at this point to fall to close to ambient pressure (˜2 psig for example). This is discussed in more detail in the inventors previously filed patent applications incorporated herein by reference.

Back Pressure Regulators for an Ozonated Water Supply Using a Pressurized Contactor with P1>1 bar. If the ozonated water supply 22 is designed to dissolve ozone gas into water at a gas pressure P1 above 1 bar, then a back pressure regulator is typically placed at the ozone off-gas outlet of the ozone-gas-water contactor and ozonated water outlet of the ozone-gas-water contactor to maintain the specified gas pressure P1 inside the contactor which is higher than pressure P2 downstream of the back pressure regulators. Once the ozone-water solution passes through the back-pressure regulator to a lower pressure the ozone gas will begin to leave the solution. If the transit time of the ozone-gas-water solution from the outlet of the ozone-gas-water contactor in the ozonated water supply 22 to the inlet of the heat exchanger 28 is relatively long, then the ozone gas will have a longer time available to leave the solution in transit from the back pressure regulator to the exchanger inlet. The dissolved ozone concentration at the exchanger inlet will be less than the dissolved ozone concentration at the outlet of the ozonated water supply 22 just downstream of the back-pressure regulator because the ozone concentration will fall toward the equilibrium concentration at the pressure downstream of the regulator. This fall in concentration can be alleviated by moving the back-pressure regulator to a point just upstream of heat exchanger 28. If the back pressure regulator set to pressure P3 is moved further downstream to a point just upstream of the dispense nozzle 36, then the decay in concentration can be reduced even further since the solution is maintained at the pressure P3>P2 until last possible moment when the solution is dispensed onto the surface of the material 38 at a pressure P2.

Back Pressure Regulators for an Ozonated Water Supply Using a Un-Pressurized Contactor with P1=1 bar. If the ozonated water supply 22 is designed to dissolve ozone gas into water at a gas pressure P1=1 bar, then a back pressure regulator can be placed at the outlet of the heat exchanger 28 to maintain a specified gas pressure P3>P1 inside the heated ozone-solvent solution which may be higher than pressure P2 downstream of the back pressure regulator. Once the ozone-water solution passes through the back-pressure regulator to a lower pressure the ozone gas will begin to leave the solution. If the transit time of the ozone-gas-water solution from the outlet of the heat exchanger 28 to the dispense nozzle 36 is relatively long, then the ozone gas will have a longer time available to leave the solution in transit from the back pressure regulator to the dispense nozzle 36. The decay in concentration can be reduced even further since the solution is maintained at the pressure P3 until last possible moment when the solution is dispensed onto the surface of the material 38 at a pressure P2.

Process Instrumentation:

The process instrumentation described above can be readily incorporated into the apparatus of FIGS. 7a, 7b, 8a, and 8b.

Treatment Solution Preparation Method and Materials Processing Method With A Spin Processor—Description and Operation—FIG. 8a

A preferred technique for applying the ozone-solvent solution to semiconductor substrates and the like is to apply the ozone-water solution to the surface of the substrate while spinning the substrate about an axis at a relatively high (1,000 to 4,000 rpm) rotational speed. The use of a this method for applying the ozone-water solution to semiconductor substrates and the like can provide a high mass transport rate of the active species to the surface of the substrate and a high mass transport of the reaction products from the surface of the substrate. One very important use of the preferred embodiments is for the removal of photoresist and organic residue from semiconductor wafers and the like. Let us describe the operation for a typical photoresist or organic residue removal application. With reference to FIG. 8a, ozononated water supply 22 supplies ozonated water formed by dissolving ozone gas at a gas phase concentration of 240 mg/L and pressure of 14.5 psia (1 bar) into DI water chilled to a temperature of about 8 degree C. The ozonated water supply delivers the chilled ozone gas-water solution at a dissolved concentration of about 70 mg/L and at a flow rate of 2.7 liter/min through three way purge valve 24, through a heater 28 where the solution temperature is increased to 42 degree C., through chemical injector/mixer, through three-way purge valve 32 to a dispense nozzle 36 where the heated ozone-water solution is applied to the center of a semiconductor wafer 38 spinning at about 1000 to 2,000 rpm. In this embodiment shown in FIG. 8a the point-of-use heater is a heat exchanger. Under these conditions the inventors have shown that the dissolved ozone concentration downstream of the point-of-use heater is approximately 60 mg/L, more than 80 percent of the concentration at the inlet of the point-of-use heater. In another embodiment that heat exchanger 28 may be a direct heater that may be heated by an number of means including resistance heating, induction heating, convection heating, microwave heating, or radiant heating. In another embodiment the heat exchanger 28 may be an injector or eductor with the relatively low temperature ozone-water solution entering the motive flow inlet, high purity steam formed from DI water introduced into the suction inlet, and the heated ozone water solution exiting from the injector or eductor outlet. The ozone-water solution traverses the surface to the wafer from the point of application to the edge of the wafer and enters the process fluid outlet of the materials-processing-module where the ozone-water solution and other liquid effluents from the process are carried through a trap to a facility drain for disposal or recycle.

Once the etch or treatment cycle is completed, the three way purge valve 32 can be set to direct the flow of the heated ozone-water solution to the facility drain/reclaim 34 for the heated ozone-water solution. The wafer can then been rinsed with DI water. The period during which the DI rinse water is applied to the spinning substrate 38 can be designated as the duration of the rinse cycle. Once the rinse cycle is completed the substrate can be spun dry using standard drying techniques or advance drying techniques such as surface tension gradient drying. The spin RPM and duration of each cycle can be set to a predetermined value for a particular process application.

Alternative Means for Applying DI Rinse Water to The Substrate. DI rinse water may be applied to the substrate with a separate set of one or more rinse nozzles (not shown). Rinse nozzles may be chosen for optimum rinse performance at a predetermined rinse flow rate and the nozzles may be positioned to rinse one or more surfaces of the substrate.

Treatment Solution Preparation Method and Materials Processing Method With A Spin Processor with Point of Use Heating—Description and Operation—FIG. 8b

In another embodiment the method and apparatus may additionally include a means for heating the ozone-water solution just upstream of the point of use as shown in FIG. 8b. The description and operation of the spin processing components shown in FIG. 8b is the same as the like numbered components shown in FIG. 8a. The description and operation of the other numbered components shown in FIG. 8b is the same as the like numbered components in FIG. 7b.

Example Process Conditions for Photoresist Removal And Post Etch Residue Removal. A typical wafer spin processing sequence my include spin etch, resist strip (resist removal), cleaning, or treatment cycle, a spin rinse cycle, and a spin dry cycle. Example process conditions for photoresist removal and post etch residue removal or for the formation of a protective film on a metal such as copper with 150 mm diameter wafers in a single wafer spin processing configuration are summarized in Table 9 below.

TABLE 9
Example Process Conditions for Photoresist Removal and Organic
Residue Removal and for the formation of a Protective Film on a
Metal such as Copper - 3 Single Wafer Processing Configuration;

| | |
|---|---|
| TREAT/ETCH/RESIST REMOVE/CLEAN | |
| Dissolved Ozone Concentration | 24 to 144 mg/L |
| (mg/L)/(millimoles/liter) | (˜0.5 to 3.0 millimoles/L) |
| Other Injected Gaseous and Liquid | See earlier discussion |
| Chemicals | |
| Hydroxyl Radical Scavenger Concentration | 2 to 10 × dissolved ozone |
| (millimoles/liter) | concentration |
| pH | ˜6 to 8.5 |
| ORP (with respect to SHE) | ˜1300 to 1100 mV |
| Ozone-Water Solution Temperature at the | ˜30 to 60+ |
| point of application (° C.) | |
| Spin Etch/Treat Speed (RPM) | 100 to 2,000 |
| Ozone-Water Solution Flow Rate (L/min) | 0.5 to 3.0 |
| Etch/Treat Duration (min) | 0.1 to 3.0 |
| RINSE | |
| DI Rinse Temperature (° C.) | 20+ |
| Spin Rinse Speed (RPM) | 1,000 to 2,000 |
| DI Rinse Flow Rate (L/min) | 0.5 to 1.0 |
| DI Rinse Duration (sec) | 5 to 20 sec |
| DRY | |
| Spin Dry Speed (RPM) | 2,000 |
| Dry Duration (min) | 10 to 30 sec |

These process conditions are typical for this type of application. However, process conditions outside the range of values presented above may also provide satisfactory performance for this and other applications and material processing configurations.
In the methods as described above the application means may include a nozzle, spray head, orifice, dispense tube or other method known to those skilled in the art for applying the ozone-solvent solution to the material.

6.3 Methods and Apparatus for Introducing and Mixing Gaseous or Liquid Chemicals

Methods and Apparatus of Introducing into Solution Gases Such as Ozone and Carbon Dixode Gas. Gases such as ozone and carbon dioxide can be dissolved into a liquid solution with a venturi injector, a packed column, hydrophobic membrane contactor. These methods and apparatus are well known to those skilled in the art. The hydrophobic membrane is preferred in many applications because it can provide a bubble free solution. Gases may be introduced using the same method and apparatus or different method and apparatus.

Methods of introducing a liquid into solution: Liquid chemicals such as TMAH (tetramethylammonium hydroxide) and H3PO4 (phosphoric acid), CH3COOH (acetic acid), or other weak carboxylic acids can be introduced into a flowing liquid with a venturi injector or a manifold coupled to the inlet of a static mixer. Liquids may also mixed in a batch using measured volumes of the chemicals. Methods of quickly mixing solutions at the point of use such as flow mixing is a preferred method when chemicals are mixed with an ozone water solution because the solution can be quickly mixed at the point of use and thereby minimize any fall in ozone concentration or consumption or degradation of the constituents as discussed above.

### 7 METHODS OF FORMING A TREATMENT SOLUTION AND APPLYING A TREATMENT SOLUTION TO A MATERIAL

One can form an ozone-water based treatment solution for corrosion free cleaning and/or surface treatment of a material including surface treatment for the formation of a protective layer or barrier layer on a material, and apply those treatment solutions to a material using an number of approaches. These approaches can be distinguished by the sequence in which the treatment composition is formed, and particularly the point at which ozone gas is added to the treatment composition. These approaches can also be distinguished by the constituents and phases applied to the substrate.

We have presented in Table 10, Table 11, and Table 12 below example methods of forming and applying ozone-solvent based compositions containing: 1) CO2 and at least one ammonia free (not containing NH3 or NH4+) base, 2) CO2 and at least one acid (H3PO4, CH3COOH, WEAK CARBOXYLIC ACID) and at least one ammonia free (not containing NH3 or NH4+) base, and 3) at least one acid (H3PO4, CH3COOH, WEAK CARBOXYLIC ACID) and at least ammonia free (not containing NH3 or NH4+) base.

TABLE 10
FORMATION & APPLICATON OF COMPOSITIONS CONTAINING CO2
AND AT LEAST ONE ADDITIONAL ACID (H3PO4, CH3COOH, WEAK
CARBOXYLIC ACID) AND AT LEAST ONE AMMONIA FREE BASE
SUCH AS TMAH

| | | | | | Continents and |
|---|---|---|---|---|---|
| | | | | | Phases |
| Method | Solution 1 | Solution 2 | Solution 3 | Solution 4 | Applied to |
| Example | (S1) | (S2) | (S3) | (S4) | Substrate |
| 1.1. Ozone | H2O + O3 + CO2 | S1 + Acid | S2 + Base | | S3 (liquid) |
| First | | | | | |
| 1.2. Ozone | H2O + O3 | S1 + CO2 | S2 + Acid | S3 + BASE | S4 (liquid) |
| First | | | | | |
| 1.3. Ozone | O3 + CO2 | S1 + H2O | S2 + Acid | S3 + BASE | S4 (liquid) |
| First | | | | | |
| 1.4. Ozone | H2O + CO2 | S1 + O3 | S2 + Acid | S3 + BASE | S4 (liquid) |
| Second | | | | | |
| 1.5. Ozone | H2O + CO2 + Acid + Base | S1 + O3 | | | S1(liquid) + O3 |
| Last | | | | | (gas) |
| 1.6. Ozone | H2O + CO2 + Acid | S1 + Base | S2 + O3 | | S2(liquid) + O3 |
| Last | | | | | (gas) |
| 1.7. Ozone | H2O + CO2 + Acid + Base | S1 + O3 | | | S1(vapor/mist) + O3 |
| Last | | | | | (gas) |
| 1.8. Ozone | H2O + CO2 + Acid | S1 + Base | S2 + O3 | | S2(vapor/mist) + O3 |
| Last | | | | | (gas) |

To aid in understanding of the summary presented in Table 10 above, and the subsequent summaries presented in the Table 11 and Table 12 below, we have presented below the detailed description of the methods of formation and application of compositions containing CO2 and at least one additional acid and at least one ammonia free base for the case when the additional acid is H3PO4 and the base is TMAH.
Method Example 1.1—Ozone First
1. (H2O+O3+CO2): Dissolve ozone gas and CO2 gas in water to form a solution 1 with a predetermined dissolved ozone concentration and predetermined dissolved CO2 (carbonic acid) concentration.
2. ((H2O+O3+CO2)+H3PO4): Add H3PO4 to solution 1 to form solution 2 with a predetermined H3PO4 concentration.
3. ((H2O+O3+CO2)+H3PO4)+TMAH): Add TMAH or other ammonia free base to solution 2 to form solution 3 at a predetermined pH.
   Method Example 1.2—Ozone First
1. (H2O+O3): Dissolved ozone gas in water to form a solution 1 with a predetermined dissolved ozone concentration
2. ((H2O+O3)+CO2)): Dissolve CO2 gas in solution 1 to form solution 2 with a predetermined dissolved CO2 (carbonic acid) concentration and dissolved ozone concentration.
4. (((H2O+O3)+CO2))+H3PO4): Add H3PO4 to solution 2 to form solution 3 with a predetermined H3PO4 concentration.
3. ((((H2O+O3)+CO2))+H3PO4)+TMAH): Add TMAH or other ammonia free base to solution 3 to form solution 4 at a predetermined pH
   Method Example 1.3—Ozone First
1. (O3+CO2): Mix CO2 gas and ozone gas at predetermined concentrations
2. ((O3+CO2)+H2O): Dissolve ozone gas and CO2 gas in water to form a solution 1 with a predetermined dissolved ozone concentration and predetermined dissolved CO2 (carbonic acid) concentration
3. (((O3+CO2)+H2O)+H3PO4): Add H3PO4 to solution 1 to form solution 2 with a predetermined H3PO4 concentration.
4. ((((O3+CO2)+H2O)+H3PO4)+TMAH): Add TMAH or other ammonia free base to solution 2 to form solution 3 at a predetermined pH
   Method Examnple 1.4—Ozone Second
1. (H2O+CO2): Dissolve CO2 gas in water to form solution 1 with a predetermined dissolved CO2 (carbonic acid) concentration
2. ((H2O+CO2)+O3): Dissolve ozone gas in solution 1 to form a solution 2 with a predetermined dissolved ozone concentration and dissolved CO2 concentration
3. (((H2O+CO2)+O3)+H3PO4): Add H3PO4 to solution 2 to form solution 3 with a predetermined H3PO4 concentration.
4. ((((H2O+CO2)+O3)+H3PO4)+TMAH): Add TMAH or other ammonia free base to solution 3 to form solution 4 at a predetermined pH
   Method Example 1.5—Ozone Last—Applicable to processes in which ozone gas is introduced into the process chamber or near the substrate surface and the final solution is formed on the substrate surface
1. (H2O+CO2+H3PO4+TMAH): Dissolve CO2 gas and H3PO4 and TMAH in water to form a solution 1 with a predetermined dissolved CO2 (carbonic acid) concentration, a predetermined H3PO4 concentration, and a predetermined pH
2. (H2O+CO2+H3PO4+TMAH)+O3):): Dissolve ozone gas in solution 1 to form solution 2 with a predetermined dissolved ozone concentration, predetermined dissolved CO2 concentration, predetermined H3PO4 concentration, and a predetermined pH
   Method Example 1.6—Ozone Last—Applicable to processes in which ozone gas is introduced into the process chamber or near the substrate surface and the final solution is formed on the substrate surface
1. (H2O+CO2+H3PO4): Dissolve CO2 gas in water and add H3PO4 to form solution 1 with a predetermined dissolved CO2 (carbonic acid) concentration and a predetermined H3PO4 concentration.
2. ((H2O+CO2+H3PO4)+TMAH): Add TMAH to solution 1 to form a solution 2 with a predetermined pH
3. (((H2O+CO2+H3PO4)+TMAH)+O3): Dissolve ozone gas in solution 2 to form solution 3 with a predetermined dissolved ozone concentration, a predetermined dissolved CO2 (carbonic acid) concentration, a predetermined H3PO4 concentration, and a predetermined pH
   Method Example 1.7—Ozone Last—Applicable to processes in which ozone gas is introduced into the process chamber, the solution is introduction is introduced into the process chamber as a vapor or mist, and the final solution is formed in the vapor phase and on the substrate surface
1. (H2O+CO2+H3PO4+TMAH): Dissolve CO2 gas in water and add H3PO4 and TMAH in water to form a solution 1 with a predetermined dissolved CO2 (carbonic acid) concentration, a predetermined H3PO4 concentration, and predetermined pH
2. (H2O+CO2+TMAH)+O3):): Dissolve ozone gas in solution 1 to form solution 2 with a predetermined dissolved ozone concentration, a predetermined dissolved CO2 concentration, a predetermined H3PO4 concentration, and a predetermined pH
   Method Example 1.8—Ozone Last—Applicable to processes in which ozone gas is introduced into the process chamber, the solution is introduction is introduced into the process chamber as a vapor or mist, and the final solution is formed in the vapor phase and on the substrate surface
1. (H2O+CO2+H3PO4): Dissolve CO2 gas in water and add H3PO4 to form solution 1 with a predetermined dissolved CO2 (carbonic acid) concentration and a predetermined H3PO4 concentration.
2. ((H2O+CO2+H3PO4)+TMAH): Add TMAH to solution 1 to form a solution 2 with a predetermined pH

(((H2O+CO2+H3PO4)+TMAH)+O3): Dissolve ozone gas in solution 2 to form solution 3 with a predetermined dissolved ozone concentration, a predetermined dissolved CO2 (carbonic acid) concentration, a predetermined H3PO4 concentration, and a predetermined pH.

TABLE 11
FORMATION & APPLICATON OF COMPOSITIONS CONTAINING CO2 AND
AT LEAST ONE AMMONIA FREE BASE SUCH AS TMAH

| | | | | | Continents and |
|---|---|---|---|---|---|
| Method | Solution 1 | Solution 2 | Solution 3 | Solution 4 | Phases Applied |
| Example | (S1) | (S2) | (S3) | (S4) | to Substrate |
| 1.1. Ozone | H2O + O3 + CO2 | S1 + Base | | | S2 (liquid) |
| First | | | | | |
| 1.2. Ozone | H2O + O3 | S1 + CO2 | S2 + Base | | S3 (liquid) |
| First | | | | | |
| 1.3. Ozone | O3 + CO2 | S1 + H2O | S2 + Base | | S3 (liquid) |
| First | | | | | |
| 1.4. Ozone | H2O + CO2 | S1 + O3 | S2 + Base | | S3 (liquid) |
| Second | | | | | |
| 1.5. Ozone | H2O + CO2 + Base | S1 + O3 | | | S1(liquid) + O3 |
| Last | | | | | (gas) |
| 1.6. Ozone | H2O + CO2 | S1 + BASE | S2 + O3 | | S2(liquid) + O3 |
| Last | | | | | (gas) |
| 1.7. Ozone | H2O + CO2 + Base | S1 + O3 | | | S1(vapor/mist) + O3 |
| Last | | | | | (gas) |
| 1.8. Ozone | H2O + CO2 | S1 + BASE | S2 + O3 | | S2(vapor/mist) + O3 |
| Last | | | | | (gas) |

TABLE 12
FORMATION & APPLICATON OF COMPOSITIONS CONTAINING AT LEAST
ONE ACID (H3PO4, CH3COOH, WEAK CARBOXYLIC ACID) AND AT LEAST
ONE AMMONIA FREE BASE SUCH AS TMAH

| | | | | | Continents and |
|---|---|---|---|---|---|
| Method | Solution 1 | Solution 2 | Solution 3 | Solution 4 | Phases Applied |
| Example | (S1) | (S2) | (S3) | (S4) | to Substrate |
| 3.1. Ozone | H2O + O3 | S1 + Acid | S2 + Base | | S3 (liquid) |
| First | | | | | |
| 3.2. Ozone | H2O + Acid | S1 + O3 | S2 + Base | | S3 (liquid) |
| Second | | | | | |
| 3.3. Ozone | H2O + Acid + Base | S1 + O3 | | | S1(liquid) + O3 |
| Last | | | | | (gas) |
| 3.4. Ozone | H2O + Acid | S1 + Base | S2 + O3 | | S2(liquid) + O3 |
| Last | | | | | (gas) |
| 3.5. Ozone | H2O + Acid + Base | S1 + O3 | | | S1(vapor/mist) + O3 |
| Last | | | | | (gas) |
| 3.6. Ozone | H2O + Acid | S1 + Base | S2 + O3 | | S2(vapor/mist) + O3 |
| Last | | | | | (gas) |

The following are variations on the above examples that apply to the preferred embodiments of the invention:
1. The method of Example 1, 2 or 3 further including the step of increasing the temperature of the treatment solution prior to supplying said treatment solution to a point of use
2. The method of Example 1, 2 or 3 further including the step of increasing the temperature of the treatment solution by flowing said treatment solution through a point of use heater prior to supplying said treatment solution to a point of use
3. The method of Example 1, 2 or 3 further including the step of applying said treatment solution to a material
4. The method of Example 1, 2 or 3 further including the step of applying said treatment solution to a material for the purpose of modifying the surface contact angle of said material
5. The method of Example 1, 2 or 3 further including the step of applying said treatment solution to a material for the purpose of cleaning said material
6. The method of Example 1, 2 or 3 further including the step of applying said treatment solution to a material for the purpose of removing an organic film from said material
7. The method of Example 1, 2 or 3 further including the step of applying said treatment solution to a material for the purpose of removing an organic residue from said material
8. The method of Example 1, 2 or 3 further including the step of applying said treatment solution to a material for the purpose of removing photoresist from film from said material
9. The method of Example 1, 2 or 3 further including the step of applying said treatment solution to a material
10. The method of Example 1, 2 or 3 further including the step of applying said treatment solution to a material for the purpose of forming a protective film on said material
11. The method of Example 1, 2 or 3 further including the step of applying said treatment solution to a material for the purpose of forming a protective film of Copper Sesquioxide (Cu2O3) on said material
12. The method of Example 1, 2 or 3 wherein said material is comprised at least in part of copper or a copper containing alloy
13. The method of Example 1, 2 or 3 wherein said material is comprised at least in part of aluminum or an aluminum containing alloy
14. The method according to Example 1, 2 or 3 wherein said solvent is water
15. The method according to Example 1, 2 or 3 wherein said ammonia free base is the metal-ion-free strong base TMAH (tetramethylammonium hydroxide)
16. The method according to Example 1, 2 or 3 wherein said ammonia free base contains one or more constituents selected from the group consisting of tetraalkyl ammonium hydroxides
17. The method according to Example 1, 2 or 3 wherein said ammonia free base contains one or more constituents selected from the group consisting of tetramethylammonium hydroxide, tetraethylammonium hydroxide, tetrapropylammonium hydroxide, tetrabutylammonium hydroxide
18. The method according to Example 1, 2 or 3 wherein said ammonia free base contains one or more constituents selected from the group consisting of quaternary ammonium hydroxides
19. The method according Example 1, 2 or 3 wherein said pH and Oxidation Reduction Potential with respect the standard hydrogen electrode is within the region for the formation of copper sesquioxide [Cu2O3] as determined from the E-pH diagram for the system under consideration.
20. The method according to Example 1, 2 or 3 wherein the dissolved CO2 concentration is the range of 1 to 20 millimoles/liter
21. The method according to Example 1, 2 or 3 wherein said pH is in the range of pH 6.0 to 9.0
22. The method of Example 1, 2 or 3 wherein the dissolved ozone concentration is the range of 1 to 200 mg/liter.
23. The method of Example 1, 2 or 3 wherein the gas phase ozone concentration is the range of 40 to 320 mg/liter.
24. The method of Example 1, 2 or 3 wherein the dissolved ozone concentration is the range of 25 to 200 mg/liter.
25. The method of Example 1, 2 or 3 where the phosphoric acid concentration is the range of 1 to 20 millimoles/liter
26. The method of Example 1, 2 or 3 where the acetic acid concentration is the range of 1 to 20 millimoles/liter.
27. The method of Example 1, 2 or 3 where the oxidation-reduction potential with respect to the standard hydrogen electrode of the composition is greater than or equal to approximately 1100 mV.
28. The method of Example 1, 2 or 3 where the oxidation-reduction potential with respect to the standard hydrogen electrode of the composition is in the range of approximately 1100 mV to 1300 mV.
29. The method of Example 1, 2 or 3 where the oxidation-reduction potential with respect to the standard hydrogen electrode of the composition is in the range of approximately 1100 mV to 1200 mV.

In the example compositions listed above, we use carbon dioxide (CO2) as a source of carbonate, phosphoric acid (H3PO4) as a source of phosphate, and acetic acid [CH3COOH] as a source of acetate. CO2, and phosphoric acid, and acetic acid are preferred because they are already available in high purity in the semiconductor fabrication facility. However, there are other sources of carbonate, phosphate, and carbonate and other bases that could be used in these compositions as discussed earlier. For example, TMA carbonate could be used as a source of carbonate, TMA phosphate could be used as a source of phosphate, and TMA acetate could be used as a source of acetate. If a liquid source of a carbonate is used such as the salt TMA carbonate (teteramethylammonium carbonate), then this liquid carbonate may be introduced and mixed as a liquid. TMA carbonate can be purchased from a chemical supplier or can be formed by dissolving CO2 gas in TMAH to form TMA carbonate. We use TAMH as the metal ion-free ammonia-free base in all the examples. There are other bases that could be used in these compositions as discussed earlier.

### 8 PROTECTIVE FILMS ON COPPER—ADDITIONAL APPLICATIONS

The stable adherent passivating films formed with the methods and apparatus and compositions of this invention may also be used for forming a protective layer on a copper surface for protection of a copper surface from damage or corrosion or contamination or surface changes caused by exposure to a liquid, gas, plasma, or other environment. Applications include but are not limited to the following examples: 1) the formation of a protective film on copper bond pads prior to wafer dicing to protect those bond pads from damage, corrosion, contamination, or undesired surface changes during the dicing (substrate sawing for example) process, 2) protection of copper from damage, corrosion, contamination, or undesired surface changes induced by exposure to a chemical mechanical polishing (CMP) step or a post CMP cleaning step, 3) protection of copper from damage or corrosion or surface changes induced by exposure to moisture, 4) protection of copper from damage or corrosion or surface changes induced by exposure to a liquid or gas or plasma, 5) protection of copper from damage, corrosion, contamination, or undesired surface changes induced by exposure to contaminants such as those encountered during wafer storage or wafer queuing times, 6) protection of copper from damage or corrosion or contamination or surface changes induced by exposure to a subsequent process step of the device manufacturing process, including but not limited to a deposition step, a plating step, a grinding or polishing step, a cleaning step, an etching step, a stripping step, a metrology step, a lithography step, a packaging step, a testing step, 7) protection of copper from damage or corrosion or surface changes induced by exposure to the environment inside the finished device package. The stable adherent passivating films formed with the methods and apparatus and compositions of this invention may also be used for forming a protective layer on an aluminum or aluminum-containing surface for protection of such surfaces from damage or corrosion or contamination or surface changes caused by exposure to a liquid, gas, plasma, or other environment.

### Post CMP and Post CMP Clean Corrosion Prevention

The compositions, methods, and apparatus of this invention can be used for treatment of surfaces for cleaning and surface treatment of surfaces containing copper or copper containing alloys as described above. Among the many applications in the cleaning and surface treatment of semiconductor wafers for passivation of the copper surface against corrosion following chemical mechanical polishing (CMP) or following post CMP cleaning. After post CMP clean, the copper surface is exposed within the fabrication environment. Copper is subject to corrosion in this ambient environment. This leads to yield loss and reliability problems. The longer the wafer is queued in the ambient environment, the greater amount of corrosion and yield loss that can occur. Despite best efforts to impose a time window between copper CMP and the next process step to reduce corrosion loss, equipment breakdown and other factors can cause queue time to exceed this target time window and lead to very high yield loss.

Copper corrosion control is a key requirement in semiconductor device manufacturing process flows when copper-based interconnect metallization is used. The inventive approach offers a number of advantages over current approaches including the following:
the present invention addresses and solves problems attendant upon tile formation of a porous and brittle copper oxide film, believed to be Cu2O and/or CuO, on the exposed upper surface of a Cu or Cu alloy interconnect following CMP; it is believed that these Cu2O and CuO layers increase in thickness during subsequent exposure of the cleaned Cu or Cu alloy surface to ambient. These copper (I) and Copper (II) oxide layers are not protective.
the present invention provides advantageously greater control of the process flow and device uniformity by selectively forming a passivating and protective and non-porous Cu2O3 layer on the exposed upper surface of a Cu or Cu alloy interconnect, e.g., subsequent to the next process step CMP (chemical mechanical polishing).
a passivating protective film can be formed with the inventive compositions and methods and apparatus without the use of organic corrosion inhibitors such as BTA
the inventive compositions and methods and apparatus may be used to remove BTA and other organic residue remaining from prior process steps
a passivating layer is purposely formed on an exposed surface of a Cu an/or Cu alloy interconnect member, thereby avoiding the adverse consequences stemming from formation of a thick porous copper oxide thereon.
the passivating film formed by the inventive compositions and methods and apparatus are formed only on the copper surface and not other surfaces such as dielectric materials
the inventive compositions have a ultra-low consumables cost
the thin passivating film is protective and yet readily removed by either dry process or wet processes
the treatment time for passivating film formation can be very short with typical treatment times of 30 to 60 seconds.

### Post Via Etch and Post Trench Etch Copper Corrosion Prevention

In a typical dual damascene integration scheme used for forming interconnects, the barrier at the bottom of the via protects the copper at the bottom of the via from oxidation and corrosion after the via etch. After the trench etch, the barrier is removed as the last step. This exposes the underlying copper to corrosion. In addition, process variation may result in the removal of the barrier at the bottom of the via after the via etch. In this case the copper may be exposed to corrosion during the queue time before the next process step (such as post etch polymer removal). Again, there is a need for a method for passivating these exposed copper surfaces to prevent corrosion prior to the next process step. The inventive methods and apparatus and treatment compositions presented here for passivating copper and copper alloys of copper can be used to protect these surfaces from corrosion and decrease yield loss.

### Copper Seed Layer Corrosion Prevention

One aspect of the invention provides for a method and apparatus and treatment composition for passivating a copper seed layer on an integrated circuit substrate. The copper may be deposited by physical vapor deposition (PVD) or other methods known to those skilled in the art. The method may also be used to provide controlled oxidation of the copper seed layer to be carried out before a copper fill or copper plating operation. The controlled oxidation may form a thin layer of a copper oxide with a thickness, which reaches a maximum value after a relatively short processing time (less than 60 seconds). While not wishing to be bound by theory, the inventors believe that the method and apparatus and treatment compositions can be used to form a thin protective copper III oxide (Cu2O3) layer. This is in contrast to the, porous, brittle, non-protective copper oxides (copper I oxide (Cu2O) and Copper II oxide (CuO)) that are known to form on copper in the ambient environment or on copper in the presence of oxygen gas or oxygen gas plasma in a process chamber.

In prior art methods, it has been found that thin layer of copper oxide, of the order of about 40 Angstroms, is most desirable as a starting point for the copper plating operation used in the formation of copper interconnects. (U.S. Pat. No 6,554,914 B1). In prior methods a thick layer of Copper I oxide (Cu2O) or copper II oxide (CuO) is formed during the air break when the seed layer deposition is completed and the plating step is completed. However, since neither copper I oxide nor copper II oxide are self limiting in thickness, the thickness of this oxide will increase with time and may grow too form a thick, porous, brittle layer. This prior method based upon the use of these oxides can provide a thick porous oxide layer and a poor starting point for copper plating, an opportunity for copper void formation, and reduced manufacturing yield. The growth of these thick porous oxides can readily occur during the queue time while the wafer awaits the next process step. The queuing time includes both the time waiting to complete a full cassette of wafers in a tool with one or more processing chambers, and also the time waiting before entering the next process tool for plating for example. In practice the queue can be extended because the equipment that is to be used for the next process step may not be available for a variety of reasons such as maintenance or repair.

### 9 METHODS AND COMPOSITIONS FOR REMOVAL OF PASSIVATING FILMS

Removal of Passivating Films at the End of the Cleaning and Passivation Cycle:

In some cases it may be desired to remove the passivating film at the end of cleaning and passivation cycle. In the case of CO2+TMAH based compositions, one method of removal of the passivating film, near the end of a treatment cycle, for example, is to stop the flow of TMAH and ozone and use just the dissolved CO2 (carbonic acid) based composition to remove the passivating film. Another method of providing such a composition is to introduce CO2 into pure DI water for use during the passivating film removal phase of a treatment cycle. The concentration of carbonic acid suitable for this passivating film formation can be readily determined in the laboratory and is expected to be in the range of 1 to 20 mM/L. In the case of CO2+H3PO4+TMAH or H3PO4+TMAH or CO2+CH3COOH+TMAH or CH3COOH+TMAH or CO2+H3PO4+CH3COOH+TMAH or H3PO4+CH3COOH+TMAH based compositions, one method of removal of the passivating film, near the end of a treatment cycle, for example, is to stop the flow of TMAH and ozone and use just a dissolved carbonic acid and/or phosphoric acid based and/or acetic acid based composition to remove the passivating film. Another method of providing such a composition is to introduce CO2 and/or phosphoric acid and/or acetic acid into pure DI water for use during the passivating film removal phase of a treatment cycle. The concentration of carbonic acid or phosphoric acid (H3PO4) suitable for this passivating film formation can be readily determined and is expected to be in the range of approximately 1 to 20 mM/L.

In other applications directed to controlled removal of copper films, one can employ a removal method comprising applying for a measured duration a composition for forming a passivating film and then applying for a measured duration a method or composition for selectively removing the passivating film without removing copper, and then repeating the cycle until the desired thickness of copper has been removed. Since the thickness of the passivating film formed is self-limiting, the method can be used to selectively remove a very thin layer of copper (less than 100 Angstroms) during each cycle. This can provide the means for selective copper removal with high precision, excellent uniformity over the wafer surface, and wide process latitude (since the removal of material during each cycle is self-limited and doesn't required a precisely timed etch. One important application could be selective formation of a precise recess in the copper film below the level of the surrounding dielectric CMP and prior to the selective deposition of a copper cap layer (a CoWP cap layer for example) so that the top surface of the cap layer can be set at a predetermined level relative to the plane of the surrounding dielectric. Example methods and apparatus and compositions for forming the passivation layer have been presented above. A typical duration for the formation and removal of the passivating film are in the range of two to ten seconds/removal cycle.

Chemicals suitable for removal of the passivating films formed are generally well known to those skilled in the art. Malachite [CuCO3Cu(OH)2] films are known to be soluble in acids including carbonic acid. Malachite films are soluble in NH4OH or KCN; both ammonia and cyanide form soluble complexes with copper. Tenorite [CuO] films are soluble in acids. Copper Sesquioxide (Cu2O3) films are soluble in acids as well. Tenorite is soluble in NH4OH or KCN. The copper phosphates are soluble in acids including phosphoric acid. Copper phosphates are soluble in NH4OH.

These passivating films may be removed by other methods well known to those skilled in the art including plasma etching, reactive ion etching, sputter etching, grinding, abrasive particle blasting, CO2 snow blasting, polishing, electrochemical etching, supercritical CO2 etching, wet chemical etching, gaseous chemical etching, laser-based or photonic-based etching.

Removal of Passivating Films Just Prior to the Next Process Step.

In most cases it is desired to remove the passivating film just prior to the next process step. In this way the metal surface can be protected from corrosion during the queue time prior to the next process step. The method of removal may be chosen for ease of integration with the next process step. For example, when the next process is a copper barrier/seed deposition process and that process is performed in a plasma chamber, then it is convenient to use plasma methods for removing the passivating film. In the case of a passivating film of Copper III oxide (Cu2O3), the film may be conveniently removed using a hydrogen containing reducing plasma (an NH3 plasma for example), ion sputtering or sputter etching, or other methods well known to those skilled in the art for removing thin oxide films in the barrier deposition tool. For example, in the case when the next process step is a copper plating process as in the case in which the passivating film is formed on the copper seed layer, the passivating film may be readily removed by the plating chemistry just as is currently practiced for the removal of ambient copper I and copper II oxides. For example, in the case in which the next process step is a dielectric barrier deposition in a CVD tool, the passivating film may again be removed by a hydrogen based reducing plasma as is currently practiced for the removal of copper I and copper II oxides formed under ambient conditions.

### 10 METHODS OF MANUFACTURING A COPPER INTERCONNECT ON A SEMICONDUCTOR WAFER

The applications of the inventive methods and apparatus and treatment compositions to wafer manufacturing are conveniently illustrated by reference to a table outline of an example copper interconnect formation process. There are many integration schemes well known to those skilled in the art. This is but one possible example scheme that exemplifies some of the key points in the process in which copper is open to corrosion.

EXAMPLE COPPER INTERCONNECT FORMATION
PROCESS-VIA-FIRST DUAL-DAMASCENE

| | PROCESS STEP | TOOL |
|---|---|---|
| 1a | Copper Oxide Reduction | DIELECTRIC DEPOSITION |
| | | TOOL |
| 1b | Dielectric Diffusion Barrier (DB)/Etch | DIELECTRIC DEPOSITION |
| | Stop Deposition (insulating SiN or SiC for | TOOL |
| | example) | |
| 1c | Via or Via and Trench Dielectric | DIELECTRIC DEPOSITION |
| | Deposition (SiCOH for example) | TOOL |
| 1d | Etch Stop Deposition (SiN for example) | DIELECTRIC DEPOSITION |
| | (optional) | TOOL |
| 1e | Line (Trench) Dielectric Deposition | DIELECTRIC DEPOSITION |
| | (optional) | TOOL |
| 1f | Hard Mask Deposition (optional) | DIELECTRIC DEPOSITION |
| | | TOOL |
| 1g | Antireflective Layer Deposition (optional) | DIELECTRIC DEPOSITION |
| | | TOOL |
| | POST DIELECTRIC QUEUING TIME | |
| 2a | Spin Resist for Via Pattern and Bake | LITHOGRAPHY TOOL SET |
| 2b | Expose Resist with Via Pattern Mask | LITHOGRAPHY TOOL SET |
| 2c | Via Resist Develop | LITHOGRAPHY TOOL SET |
| | POST VIA LITHO QUEUING TIME | |
| 3a | Etch Vias Down Through Entire Dielectric | DIELECTRIC ETCH TOOL |
| | Layer (Stop on DB/Etch Stop at Bottom of | |
| | Dielectric Stack) | |
| 3b | Post Via Etch Resist Strip - Plasma | DIELECTRIC ETCH TOOL |
| | POST VIA ETCH QUEUING TIME | CRITICAL CORROSION |
| | | PERIOD IF COPPER IS |
| | | EXPOSED |
| 4a | Post Via Etch Strip Polymer Clean | SINGLE-WAFER WET |
| | | POLYMER CLEAN |
| | POST VIA POLYMER CLEAN | |
| | QUEUING TIME | |
| 5a | Spin BARC & Resist for Trench Pattern | LITHOGRAPHYTOOL SET |
| | and Bake | |
| 5b | Expose Resist with Trench Pattern Mask | LITHOGRAPHY TOOL SET |
| 5c | Trench Resist Develop | LITHOGRAPHY TOOL SET |
| | POST TRENCH LITHO QUEUING TIME | |
| 6a | Etch Trenches - Stop on Embedded Etch | DIELECTRIC ETCH TOOL |
| | Stop If Etch Stop is Present | |
| 6b | Post Trench Etch Resist Strip - Plasma | DIELECTRIC ETCH TOOL |
| 6c | Remove BARC from Via Bottom - Plasma | DIELECTRIC ETCH TOOL |
| 6d | Remove Diffusion Barrier Layer/Etch Stop | DIELECTRIC ETCH TOOL |
| | at Bottom of Via (SiN) | |
| 6e | Remove BARC Residue from Via Bottom - | DIELECTRIC ETCH TOOL |
| | Plasma | |
| | POST TRENCH ETCH QUEUING TIME | CRITICAL CORROSION |
| | | PERIOD SINCE COPPER IS |
| | | EXPOSED |
| 7a | Post Trench Etch Strip Polymer Clean | SINGLE-WAFER WET |
| | | POLYMER CLEAN |
| | POST TRENCH POLYMER CLEAN | |
| | QUEUING TIME | |
| 8a | Copper Oxide Reduction or Sputter Clean | COPPER BARRIER-SEED |
| | Copper | DEPOSITION TOOL |
| 8b | Copper Barrier Layer Deposition | COPPER BARRIER-SEED |
| | (conductive TaN for exampe) | DEPOSITION TOOL |
| 8c | Copper Seed Layer Deposition (Cu) | COPPER BARRIER-SEED |
| | | DEPOSITION TOOL |
| | POST COPPER SEED QUEUING TIME | CRITICAL CORROSION |
| | | PERIOD SINCE COPPER IS |
| | | EXPOSED |
| 9a | Copper Electrofill (plating) (Cu) | COPPER |
| | | ELECTROPLATING TOOL |
| | POST COPPER ELECTROFILL (plating) | |
| | QUEUING TIME | |
| 10a | Copper CMP | COPPER CMP/POST CMP |
| | | CLEAN TOOL |
| 10b | Post CMP Clean Integrated w/ next step | COPPER CMP/POST CMP |
| | | CLEAN TOOL |
| 10c | Post Cu CMP Organic Clean and Cu | COPPER CMP/POST CMP |
| | Passivation - Organic Copper Passivation | CLEAN TOOL |
| | Coating | |
| | POST COPPER CMP QUEUING TIME | CRITICAL CORROSION |
| | | PERIOD SINCE COPPER IS |
| | | EXPOSED |
| | Return to First Step for next interconnect | DIELECTRIC DEPOSITION |
| | layer | TOOL |

### Stripping and Cleaning and Passivation

### Example Potential Applications

### Example Applications when the Resist Removal Capability, Light Organic Cleaning Capability, and/or Copper Passivation Capability is Considered

GROUP A—Resist Strip, Post Ash Clean, and Copper Passivation:

Post-Via-Etch: Resist Removal and Copper Passivation in lieu of plasma ash resist strip (Prior To Via Polymer Wet Clean)
Post-Trench-Etch: Resist Removal and Copper Passivation in lieu of plasma ash resist strip (Prior To Trench Polymer Wet Clean)
TOOL INTEGRATION APPROACH EXAMPLE 1: stand alone tool as a 60 to 120 second strip and clean and passivate step prior to polymer clean
TOOL INTEGRATION APPROACH EXAMPLE 2: integrated into polymer cleaning tool as a 60 to 120 second strip and clean and passivate step prior to polymer clean
Post-Via-Ash: Clean and Copper Passivation (Prior To Via Polymer Wet Clean)
Post-Trench-Ash: Clean and Copper Passivation (Prior To Trench Polymer Wet Clean)
TOOL INTEGRATION APPROACH EXAMPLE 1: stand alone tool as a short 30 to 60 second clean and passivate step prior to polymer clean (passivate and queue for polymer cleaning)
TOOL INTEGRATION APPROACH EXAMPLE 2: integrated into polymer cleaning tool as a short 30 to 60 second clean and passivate step prior to polymer clean (passivate and queue for polymer cleaning)
Post-Via-Polymer-Clean: Organic Clean and Copper Passivation (After Via Polymer Wet Clean)
Post-Trench-Polymer-Clean: Organic Clean and Copper Passivation (After Trench Polymer Wet Clean)
TOOL INTEGRATION APPROACH EXAMPLE: integrated into polymer cleaning tool as a short 30 second light organic clean and passivate step after polymer clean
   GROUP B—Copper Passivation:
Post-Copper-Seed-Deposition: Copper Passivation (Prior To Wet Copper Plating)
TOOL INTEGRATION APPROACH EXAMPLE 1: stand alone tool as a short 30 to 60 second clean and passivate step prior to copper plating (passivate and queue for plating)
TOOL INTEGRATION APPROACH EXAMPLE 2: integrated into copper plating tool as a short 30 to 60 second clean and passivate step prior to copper plating (passivate and queue for plating)
   GROUP C—Light Organic Cleaning (plating additive removal) and Copper Passivation:
Post-Copper-Electrofill (Plating): Light Organic Cleaning and Copper Passivation (After Wet Copper Plating)
TOOL INTEGRATION APPROACH EXAMPLE 1: integrated into copper plating tool as a short 30 to 60 second clean and passivate step after copper plating
   GROUP D—Light Organic Cleaning (Organic Corrosion Inhibitor Removal) and Copper Passivation:
Post-CMP: Light Organic Clean and Copper Passivation (After Wet CMP)
TOOL INTEGRATION APPROACH EXAMPLE: integrated into CMP/PostCMP cleaning tool as short 30 to 60 second clean and passivate step after CMP
Post-CMP-Clean: Light Organic Clean Copper Passivation (After Wet CMP Clean)
TOOL INTEGRATION APPROACH EXAMPLE: integrated into CMP/PostCMP cleaning tool as a short 30 to 60 second clean and passivate step after Post CMP Clean
   Post Trench Etch Resist Removal and Clean:

In current integration schemes, the barrier layer (SiN or SiC for example) is removed after the plasma based resist strip step. This protects the copper from oxidation by the oxygen plasma used in the resist strip step.

The removal of resist can be performed using the inventive compositions while passivating any exposed copper surfaces. Accordingly, the resist removal step can be performed after the barrier is open. This can then be followed by a wet polymer removal step. In one embodiment the resist removal step and polymer removal step can be performed on one single wafer processing tool with the wafer first stripped and then cleaned. In addition, the chemistry may optionally be applied after the polymer removal step to remove any organic residue remaining and passivate the copper surface. The passivating layer can then be removed just prior to deposition of the copper barrier layer and the copper seed layer using methods described above.

Post Cmp Clean and Passivation Used Prior to the Deposition of a Cap Layer:

The copper surface must be free of any organic contamination such as residual BTA and thick porous layers of and copper I or copper II oxide prior to the deposition of the cap layer (a CoWP layer deposited by electroless deposition for example) through the use of cleaning agents to remove the BTA and the tight control of the queue time between the CMP step and the cap layer deposition step. The use of the compositions of this invention can not only remove the organic contamination from the surface of the wafer but also passivate the surface and prevent the formation of thick layers of copper I or copper II oxide. This can not only increase yield, but also provide a larger process window and eliminate the requirement on short queue time. The passivating layer can then be removed just prior to deposition of the cap layer using methods described above.

### General Comments

In many instances in the above description of the preferred embodiments we have specified typical ranges of parameters. Whereas these ranges of values may be preferred, conditions outside these ranges of values may be operable as well. In many instances in the above discussion we refer to the use of an ammonia (NH3 OR NH4+) free base which does not form soluble complexes with copper. In general this includes the use of a base or salt not containing any species that forms soluble complexes with copper, said species including but not limited to NH3 or NH4+. Although specific features of the preferred embodiments are shown in some drawings and not others, this is for convenience only as many features may be combined with any or all of the other features. The contents of the preceding discussion and the drawings are set forth as examples only and should not be understood to represent limitations upon the scope of the present invention.

One could use a similar approach for formulating a copper compatible passivating treatment chemistry for use with other oxidizers, such as hydrogen peroxide solutions, in lieu of ozone-water solutions using the teaching presented herein. However, these latter formulations with these lower Eh (oxidation-reduction potential with respect to the standard hydrogen electrode) values will not form Cu2O3 passivating films as in the case of the ozone-water based formulations. In the above discussed ozone-water based compositions the stable solid phase formed on exposed copper surfaces is believed to be Cu2O3 (copper sesquioxide) for the pH range of approximately 5.7 to 8.5 where Eh ranges from approximately 1350 mV to 1150 mV. Accordingly, the film which forms at these lower Eh values may not be perfectly protective and the copper etch rate may be higher.

In case of embodiments using ozone, or other oxidizers such as hydrogen peroxide, with compositions containing both CO2 and H3PO4, these compositions can have E-pH values (Potential with respect to the standard hydrogen electrode-pH values) which lie within the region of Cu3(PO4)2 or CuO film formation for the Cu—CO2—H3PO4—H2O system as shown on the Cu—CO2—H3PO4—H2O system E-pH diagram. (FIGS. 6a and 6b)

In case of embodiments using ozone, or other oxidizers such as hydrogen peroxide, with compositions containing H3PO4 and lower concentrations of dissolved CO2 (<0.5 mM/L for example) these chemical compositions can have E-pH values that lie within the region of Cu3(PO4)2 or CuO film formation for the Cu—H3PO4—H2O system as shown on the Cu—H3PO4—H2O system E-pH diagram (See FIGS. 3a and 3b).

In case of embodiments using ozone, or other oxidizers such as hydrogen peroxide, with compositions containing both CO2 and CH3COOH, these compositions can have E-pH values (Potential with respect to standard hydrogen electrode-pH values) which lie within the region of CuO film formation for the Cu—CO2—CH3COOH—H2O system as shown on the Cu—CO2—CH3COOH—H2O system E-pH diagram (See FIGS. 4a, 4b, 5a, and 5b).

1. In a method of manufacturing a circuit or interconnect on a substrate wherein the circuit or interconnect comprises copper or a copper-containing alloy, the step of treating said substrate with an ozone-solvent-based treatment composition to form an inorganic passivating layer on said copper or said copper-containing alloy.

2. The method of claim 1 wherein said ozone-solvent-based treatment composition comprises ozone gas dissolved in a solvent, at least one acid, and a sufficient amount of a base or salt not containing any species that forms soluble complexes with copper, said species including but not limited to NH3 or NH4+, such that said composition has predetermined values of both pH and corresponding Eh (oxidation-reduction potential).

3. The method of claim 2 wherein said base is selected from the group consisting of quaternary ammonium hydroxides, tetraalkyl ammonium hydroxides, tetramethylammonium hydroxide, tetraethylammonium hydroxide, tetrapropylammonium hydroxide, tetrabutylammonium hydroxide.

4. The method of claim 2 wherein said salt is selected from the group consisting of quaternary ammonium carbonate, bicarbonate, phosphate, and acetate salts, including but not limited to tetraalkyl ammonium carbonates, tetraalkyl ammonium bicarbonates, tetraalkyl phosphates, tetraalkyl ammonium acetates, and other salts of weak carboxylic acids.

5. The method of claim 2 wherein said salt is selected from the group consisting of quaternary ammonium molybdate, chromate, dichromate, silicate, vandate, and borate salts, including but not limited to tetraalkyl ammonium molybdates, tetraalkyl ammonium chromates, tetraalkyl ammonium dichromates, tetraalkyl ammonium silicates, tetraalkyl ammonium vandate and tetraalkyl ammonium borates.

6. The method of claim 1 wherein said solvent is water.

7. The method of claim 2 wherein said at least one acid is selected from the group consisting of CO2, H2CO2, H3PO4, CH3COOH, and a weak carboxylic acid.

8. The method of claim 7 wherein the weak carboxylic acid is selected from the group consisting of formic(methanoic) acid, propanoic (propionic) acid, butanoic (butyric) acid, pentanoic(valeric) acid, hexanoic(caproic) acid, heptanoic (enanthic) acid, actanoic(caprylic) acid, nonanoic(pelargonic) acid and decanoic(capric) acid.

9. The method of claim 2 wherein said composition has an oxidation-reduction potential with respect to standard hydrogen electrode greater than or equal to approximately 1100 mV.

10. The method of claim 9 wherein said composition has a pH is in the range of approximately 6 to 8.5.

11. The method of claim 9 wherein said composition has a pH is in the range of approximately 5 to 9.0.

12. The method of claim 2 wherein with respect to an E-pH diagram for said composition, said composition has an oxidation-reduction potential with respect to standard hydrogen electrode and a pH corresponding to formation of Cu2O3.

13. The method of claim 2 wherein said inorganic passivating layer comprises Cu2O3.

14. The method of claim 1 wherein the temperature of the composition at said layer is in the range of 5° C. to 95° C.

15. The method of claim 14 wherein the temperature of the composition at said layer is in the range of 40° C. to 65° C.

16. The method of claim 14 wherein after the step of treating and immediately before a subsequent process step, the passivating layer is removed from exposed copper or copper-containing alloy surfaces.

17. The method of claim 14 wherein, after the step of treating, said passivating layer is removed.

18. The method of claim 14 wherein said passivating layer is removed using at least one of the following: a hydrogen-containing reducing chemistry, inert gas sputtering, plasma etching, or a wet chemistry in which the passivating layer is soluble.

19. The method of claim 14 further including the step of forming the ozone-solvent-based treatment composition at a relatively low first temperature where the solubility of ozone gas in the solvent is relatively high.

20. The method of claim 14 further including the step of heating the ozone-based treatment composition, and wherein the step of treating comprises applying said heated ozone-based treatment composition to the substrate.

21. The method of claim 14 wherein the step of heating forms a supersaturated ozone-solvent based treatment composition, and wherein the step of treating comprises applying said supersaturated ozone-solvent based treatment composition to the substrate.

22. The method of claim 14 further including reacting the ozone-solvent-based treatment composition with the surface of the substrate at a temperature higher than that at which the ozone-solvent-based treatment composition was initially formed.

23. The method of claim 14 wherein said inorganic passivating layer is selected from the group consisting of Cu2O3, malachite, a copper phosphate, a triplex passive layer structure Cu2O/CuO/Cu2O3, a triplex passive layer structure Cu2O/malachite/Cu2O3, and a triplex passive layer structure Cu2O/a copper phosphate/Cu2O3.

24. The method of claim 14 wherein the wafer further includes a material selected from the group consisting of photoresist, BARC, ARC, via fill material, organic corrosion inhibitor, organic residue, and an organic film; and
wherein said ozone-solvent based treatment composition at least partially removes said material.

25. The method of claim 14 further including measuring at least one parameter selected from the group consisting of pH, and ORP; controlling the addition of at least one acid or at least one base or salt to said ozone-solvent based treatment composition to maintain said parameter within a predetermined range.

26. A system for use in manufacturing a circuit or interconnect on a substrate wherein the circuit or interconnect comprises copper or a copper-containing alloy comprising:
a source of solvent;
a source of ozone gas;
a source of at least one acid;
a source of a least one base or salt not containing any species that forms soluble complexes with copper, said species including but not limited to NH3 or NH4+.

27. A system as in claim 26 further comprising an ozone-gas contactor for dissolving ozone gas into said solvent to form an ozone-solvent solution.

28. A system of claim 27 further comprising a means for introduction of said at least one acid into at least one of said ozone gas, said solvent, said ozone gas contactor and said ozone-solvent solution.

29. A system of claim 28 further comprising a means for introduction of said at least one base or salt into at least one of said solvent, said ozone gas contactor, and said ozone-solvent solution;
wherein said system is to configured such that said at least one base or salt is injected after said acid in forming a final solution, so as to control pH of the final solution to insure that the pH does not rise above a predetermined maximum pH.

30. A system of claim 29 further comprising one or more sensors to measure at least one of ORP and pH of the final solution in order to monitor the ORP and/or the pH of the final solution.

31. A system of claim 26 further comprising a heater configured to heat said ozone-solvent solution prior to the application of said ozone-solvent solution to said substrate

32. A system of claim 29 further comprising a heater configured to heat said final solution prior to the application of said final solution to said substrate.

33. A system of claim 29 further comprising a heater configured to heat said final solution during the application of said final solution to said substrate.

34. A system of claim 29 further comprising at least one controller configured to vary the amount of acid or base or salt added to the final solution to set the pH and ORP of the final solution within a predetermined range.

35. An interconnect or circuit formed by the process of claim 1.
